(19) United States
(12) Patent Application Publication
(10) Pub. No.: US 2026/0059754 A1
(43) Pub. Date: Feb. 26, 2026

(54) SEMICONDUCTOR MEMORY DEVICE

(71) Applicant: Kioxia Corporation, Tokyo (JP)

(72) Inventor: Koki TANIYAMA, Yokkaichi Mie (JP)

(21) Appl. No.: 19/069,362

(22) Filed: Mar. 4, 2025

(30) Foreign Application Priority Data
Aug. 23, 2024 (JP) 2024-143111

(51) Int. Cl. H10B 43/27; H10B 43/35

(52) U.S. Cl. CPC H10B 43/27; H10B 43/35

(57) ABSTRACT

A semiconductor memory device includes an insulating member provided between a first semiconductor pillar and a second semiconductor pillar. The insulating member overlaps a portion of the first semiconductor pillar and a portion of the second semiconductor pillar, extends in a first direction, and divides a portion of a plurality of conductive layers stacked in a stacking direction. A first width of the insulating member at a position in the stacking direction corresponding to a first conductive layer of the conductive layers is larger than a second width of the insulating member at a position in the stacking direction corresponding to end regions of the first and second semiconductor pillars and on a side of the plurality of conductive layers with respect to a first contact electrode and a second contact electrode.

### CROSS-REFERENCE TO RELATED APPLICATION

This application is based upon and claims the benefit of priority from Japanese Patent Application No. 2024-143111, filed Aug. 23, 2024, the entire contents of which are incorporated herein by reference.

### FIELD

Embodiments described herein relate generally to a semiconductor memory device.

### BACKGROUND

There is known a semiconductor memory device including a plurality of conductive layers stacked in a stacking direction, a semiconductor pillar that extends in the stacking direction and faces the plurality of conductive layers, and a gate insulating film provided between the plurality of conductive layers and the semiconductor pillar. The gate insulating film includes a charge storage film such as silicon nitride (SiN).

### DESCRIPTION OF THE DRAWINGS

FIG. 1 is a schematic circuit diagram illustrating a configuration of a semiconductor memory device according to a first embodiment.

FIG. 2 is a schematic plan view illustrating a configuration of a portion of the semiconductor memory device.

FIG. 3 is a schematic plan view illustrating a configuration of a portion of the semiconductor memory device.

FIG. 4 is a schematic sectional view illustrating a configuration of a portion of the semiconductor memory device.

FIG. 5 is a schematic sectional view illustrating a configuration of a portion of the semiconductor memory device.

FIG. 6 is a schematic sectional view illustrating a configuration of a portion of the semiconductor memory device.

FIG. 7 is a schematic sectional view illustrating a configuration of a portion of the semiconductor memory device.

FIG. 8 is a schematic sectional view illustrating a method for manufacturing a semiconductor memory device according to the first embodiment.

FIG. 9 is a schematic sectional view illustrating the same manufacturing method.

FIG. 10 is a schematic sectional view illustrating the same manufacturing method.

FIG. 11 is a schematic sectional view illustrating the same manufacturing method.

FIG. 12 is a schematic sectional view illustrating the same manufacturing method.

FIG. 13 is a schematic sectional view illustrating the same manufacturing method.

FIG. 14 is a schematic sectional view illustrating the same manufacturing method.

FIG. 15 is a schematic sectional view illustrating the same manufacturing method.

FIG. 16 is a schematic sectional view illustrating the same manufacturing method.

FIG. 17 is a schematic sectional view illustrating the same manufacturing method.

FIG. 18 is a schematic sectional view illustrating the same manufacturing method.

FIG. 19 is a schematic sectional view illustrating the same manufacturing method.

FIG. 20 is a schematic sectional view illustrating the same manufacturing method.

FIG. 21 is a schematic sectional view illustrating the same manufacturing method.

FIG. 22 is a schematic sectional view illustrating the same manufacturing method.

FIG. 23 is a schematic sectional view illustrating the same manufacturing method.

FIG. 24 is a schematic sectional view illustrating the same manufacturing method.

FIG. 25 is a schematic sectional view illustrating the same manufacturing method.

FIG. 26 is a schematic sectional view illustrating the same manufacturing method.

FIG. 27 is a schematic sectional view illustrating the same manufacturing method.

FIG. 28 is a schematic sectional view illustrating the same manufacturing method.

FIG. 29 is a schematic sectional view illustrating the same manufacturing method.

FIG. 30 is a schematic sectional view illustrating the same manufacturing method.

FIG. 31 is a schematic sectional view illustrating the same manufacturing method.

FIG. 32 is a schematic sectional view illustrating the same manufacturing method.

FIG. 33 is a schematic sectional view illustrating a configuration of a portion of a semiconductor memory device according to a second embodiment.

FIG. 34 is a schematic sectional view illustrating a configuration of a portion of the semiconductor memory device.

FIG. 35 is a schematic sectional view illustrating a configuration of a portion of the semiconductor memory device.

FIG. 36 is a schematic sectional view illustrating a configuration of a portion of a semiconductor memory device according to a third embodiment.

FIG. 37 is a schematic sectional view illustrating a configuration of a portion of the semiconductor memory device.

FIG. 38 is a schematic sectional view illustrating a configuration of a portion of a semiconductor memory device according to a fourth embodiment.

FIG. 39 is a schematic sectional view illustrating a configuration of a portion of the semiconductor memory device.

FIG. 40 is a schematic sectional view illustrating a method for manufacturing a semiconductor memory device according to the fourth embodiment.

FIG. 41 is a schematic sectional view illustrating the same manufacturing method.

FIG. 42 is a schematic sectional view illustrating the same manufacturing method.

FIG. 43 is a schematic sectional view illustrating a configuration of a portion of a semiconductor memory device according to a fifth embodiment.

### DETAILED DESCRIPTION

In general, according to one embodiment, a semiconductor memory device includes: a plurality of conductive layers stacked in a stacking direction and extending in a first direction intersecting with the stacking direction; a first semiconductor pillar extending in the stacking direction, facing the plurality of conductive layers, and including impurities in a first end region along the stacking direction; a first gate insulating film provided between the plurality of conductive layers and the first semiconductor pillar; a first contact electrode connected to the first end region; a second semiconductor pillar spaced from the first semiconductor pillar in a second direction intersecting with the stacking direction and the first direction, extending in the stacking direction, facing the plurality of conductive layers, and including impurities in a second end region along the stacking direction; a second gate insulating film provided between the plurality of conductive layers and the second semiconductor pillar; a second contact electrode connected to the second end region; and an insulating member provided between the first semiconductor pillar and the second semiconductor pillar, the insulating member overlapping a portion of the first semiconductor pillar and a portion of the second semiconductor pillar when viewed in the stacking direction, extending in the first direction, and dividing a portion of the conductive layers arranged on a side of the first contact electrode and the second contact electrode in the stacking direction among the plurality of conductive layers in the second direction. A first width of the insulating member in the second direction at a position in the stacking direction corresponding to a first conductive layer of the conductive layers divided in the second direction by the insulating member is larger than a second width of the insulating member in the second direction at a position in the stacking direction corresponding to the first end region and the second end region and on a side of the plurality of conductive layers with respect to the first contact electrode and the second contact electrode.

Next, a semiconductor memory device according to an embodiment will be described in detail with reference to the drawings. The following embodiment is merely an example and is not intended to limit the present disclosure. In addition, the following drawings are schematic, and some configurations may be omitted for the sake of description. In addition, parts common to embodiments are designated by the same reference numerals, and descriptions thereof may be omitted.

In addition, in this specification, the term “semiconductor memory device” may refer to a memory die, or may refer to a memory system including a controller die, such as a memory chip, a memory card, or a solid state drive (SSD). It may also refer to a configuration that includes a host computer, such as a smart phone, tablet, or personal computer.

In addition, in this specification, when it is said that a first component is “electrically connected” to a second component, the first component may be directly connected to the second component, or the first component may be connected to the second component via wiring, a semiconductor member, a transistor, or the like. For example, if three transistors are connected in series, the first transistor is “electrically connected” to the third transistor even if the second transistor is in an OFF state.

In addition, in this specification, when it is said that a first configuration is “connected between” a second configuration and a third configuration, it may mean that the first configuration, the second configuration, and the third configuration are connected in series, and that the second configuration is connected to the third configuration via the first configuration.

In this specification, a predetermined direction parallel to an upper surface of a substrate is called an X direction, a direction parallel to the upper surface of the substrate and perpendicular to the X direction is called a Y direction, and a direction perpendicular to the upper surface of the substrate is called a Z direction.

In this specification, the direction that intersects with the surface of the substrate is sometimes called a stacking direction. In addition, a direction along a predetermined surface that intersects with the stacking direction is sometimes called a first direction, and a direction that intersects with the first direction along this surface is sometimes called a second direction. The stacking direction may or may not coincide with the Z direction. In addition, the first direction and the second direction may or may not correspond to either the X direction or the Y direction.

In addition, in this specification, expressions such as “up” and “down” are based on the substrate. For example, the direction away from the substrate along the Z direction is called “up”, and the direction approaching the substrate along the Z direction is called “down”. In addition, when referring to a certain component, a lower surface or a lower end refers to the surface or end of the component facing the substrate, and when referring to the upper surface or upper end, refers to the surface or end of the component facing away from the substrate. In addition, the surfaces that intersect with the X or Y direction are called sides, and the like.

In addition, in this specification, when referring to a configuration, member, and the like, “width”, “length”, or “thickness” in a predetermined direction, it may mean the width, length, or thickness in a cross section observed by a scanning electron microscopy (SEM) or a transmission electron microscopy (TEM), or the like.

### First Embodiment

### Configuration

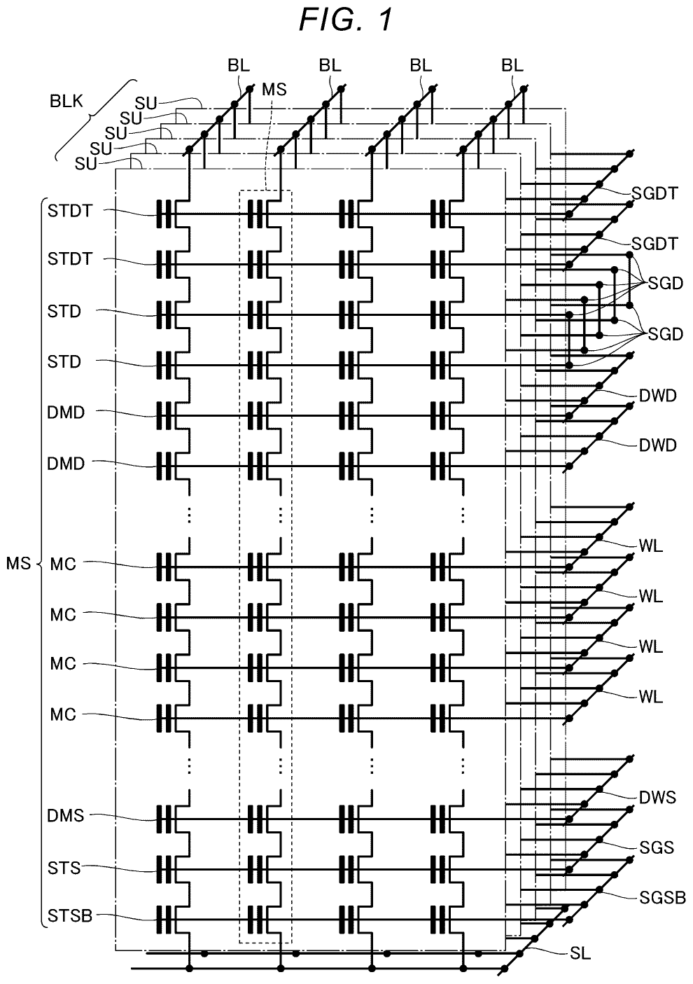

FIG. 1 is a schematic circuit diagram illustrating a configuration of a semiconductor memory device according to a first embodiment. The semiconductor memory device according to the present embodiment is provided with a memory cell array.

The memory cell array includes a plurality of memory blocks BLK. The plurality of memory blocks BLK each have a plurality of string units SU. The plurality of string units SU each have a plurality of memory strings MS. One end of each of the plurality of memory strings MS is connected to a peripheral circuit (not shown) via a bit line BL. Also, the other end of each of the plurality of memory strings MS is connected to a peripheral circuit (not shown) via a common source line SL.

The memory string MS is provided with drain-side select transistors STDT and STD, one or more drain-side dummy memory cells DMD, a plurality of memory cells MC (memory transistor), one or more source-side dummy memory cells DMS, and source-side select transistors STS and STSB. The drain-side select transistors STDT and STD, the drain-side dummy memory cell DMD, the plurality of memory cells MC, the source-side dummy memory cell DMS, and the source-side select transistors STS and STSB are connected in series between the bit line BL and the source line SL. Hereinafter, the drain-side select transistors STDT and STD and the source-side select transistors STS and STSB may be simply referred to as a select transistor (STDT, STD, STS, or STSB). Further, the drain-side dummy memory cell DMD and the source-side dummy memory cell DMS may be simply referred to as a dummy memory cell (DMD or DMS).

The memory cell MC is a field effect transistor. The memory cell MC is provided with a portion of the semiconductor pillar, a gate insulating film, and a gate electrode. A portion of the semiconductor pillar described above functions as a channel region. The gate insulating film includes a charge storage film. A threshold voltage of the memory cell MC changes depending on the amount of charge in the charge storage film. The memory cell MC stores one or more bits of data. In addition, word lines WL are respectively connected to the gate electrodes of the plurality of memory cells MC corresponding to one memory string MS. These word lines WL are commonly connected to all memory strings MS in one memory block BLK.

The dummy memory cell (DMD or DMS) is a field effect transistor. The dummy memory cell (DMD or DMS) is configured in the same manner as the memory cell MC. However, the dummy memory cell (DMD or DMS) is not used for storing data. The drain-side dummy memory cell DMD is disposed between the memory cell MC and the drain-side select transistor STD. The source-side dummy memory cell DMS is disposed between the memory cell MC and the source-side select transistor STS. The dummy memory cell (DMD or DMS) reduces the potential gradient between the memory cell MC and the select transistor (STD, STS) during a read operation, a write operation, an erase operation, and the like. A drain-side dummy word line DWD is connected to the gate electrode of one or more drain-side dummy memory cells DMD corresponding to one memory string MS. A source-side dummy word line DWS is connected to the gate electrode of one or more source-side dummy memory cells DMS corresponding to one memory string MS. The drain-side dummy word line DWD and the source-side dummy word line DWS are each commonly connected to all memory strings MS in one memory block BLK.

The select transistor (STDT, STD, STS, or STSB) is a field effect transistor. The select transistor (STDT, STD, STS, or STSB) is provided with a portion of the semiconductor pillar, a gate insulating film, and a gate electrode. A portion of the semiconductor pillar described above functions as a channel region. A selection gate line (SGDT, SGD, SGS, or SGSB) is connected to the gate electrode of the select transistor (STDT, STD, STS, or STSB). One drain-side selection gate line SGDT is commonly connected to all memory strings MS in one memory block BLK. One drain-side selection gate line SGD is commonly connected to all memory strings MS in one string unit SU. In the illustrated example, the gate electrodes of all the drain-side select transistors STD in one memory string MS are connected to a common drain-side selection gate line SGD. The drain-side selection gate line SGD is electrically independent for each string unit SU. One source-side selection gate line SGS is commonly connected to all memory strings MS in one memory block BLK. One source-side selection gate line SGSB is commonly connected to all memory strings MS in one memory block BLK.

Each wiring in the memory cell array illustrated in FIG. 1 is electrically connected to a peripheral circuit (not shown). The peripheral circuit is provided with, for example, a voltage generation circuit that generates an operating voltage, a voltage transfer circuit that transfers the generated operating voltage to the selected bit line BL, the word line WL, the dummy word line (DWD, or DWS), the source line SL, and the selected gate line (SGDT, SGD, SGS, or SGSB), a sense amplifier module connected to the bit line BL, and a sequencer that controls these.

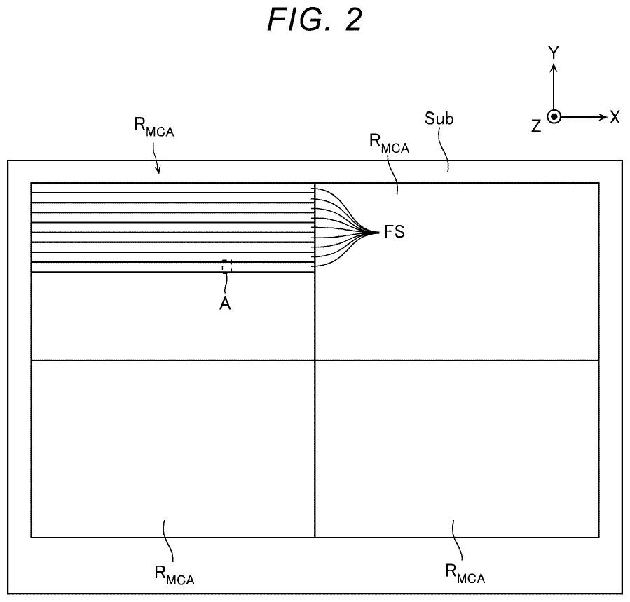

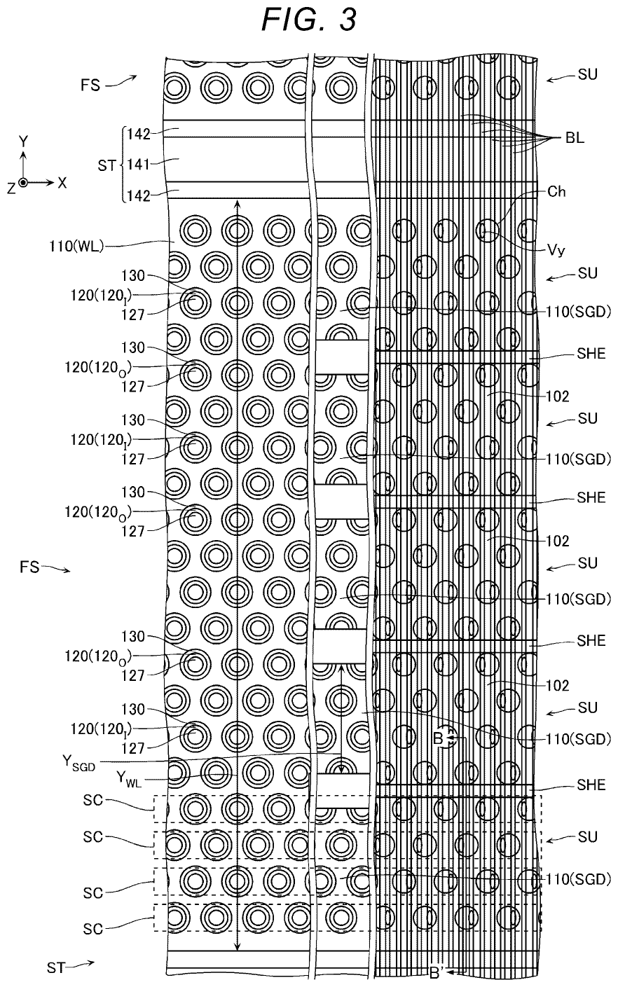

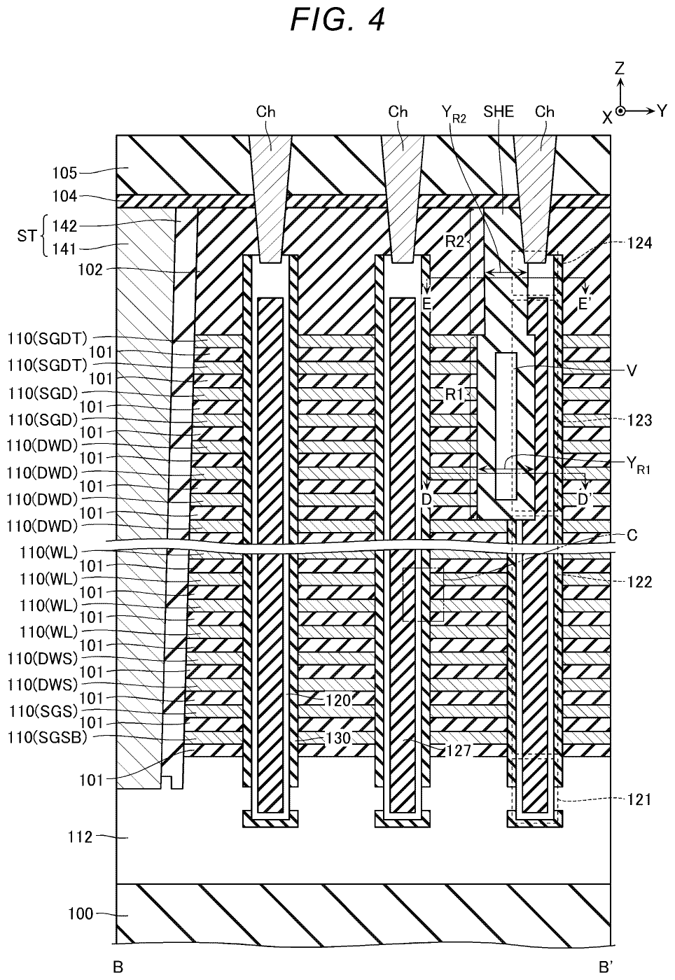

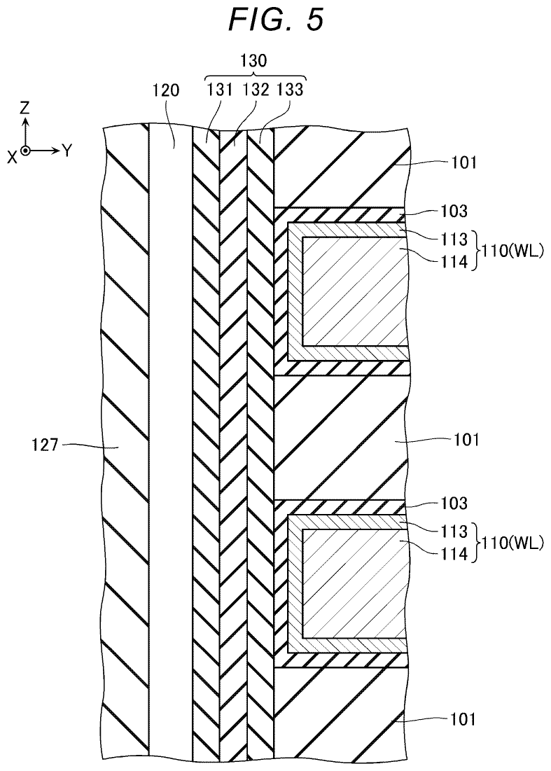

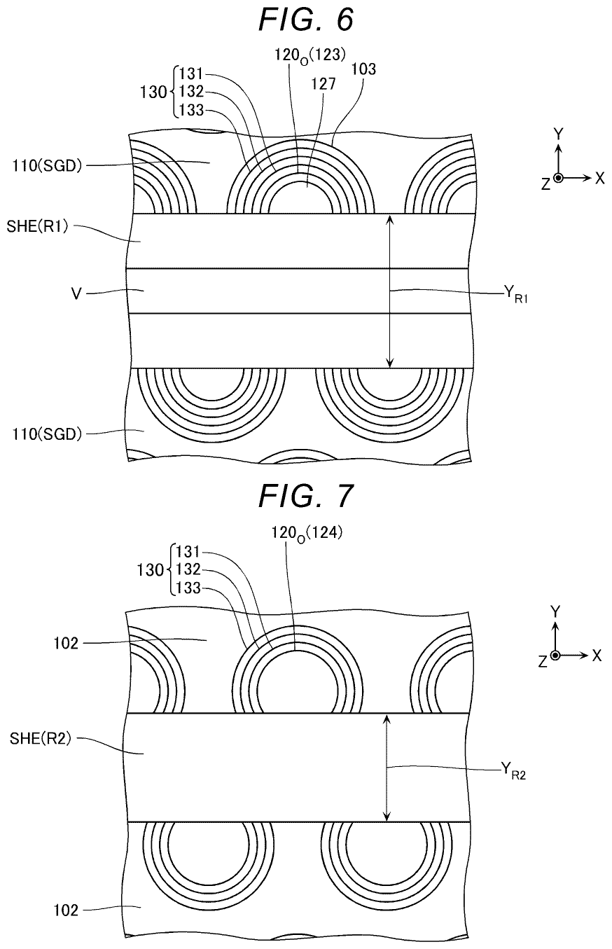

Next, a configuration example of the semiconductor memory device according to the first embodiment will be illustrated with reference to FIGS. 2 to 7. FIG. 2 is a schematic plan view illustrating a configuration of a portion of the semiconductor memory device. FIG. 3 is a schematic plan view illustrating a configuration of a portion of the semiconductor memory device, and illustrates an enlarged view of a part indicated by A in FIG. 2. In addition, a portion of FIG. 3 illustrates an XY cross section at a height position corresponding to a conductive layer 110 (WL) described later. Further, a portion of FIG. 3 illustrates an XY cross section at a height position corresponding to a conductive layer 110 (SGD) described later. In addition, in a portion of FIG. 3, insulating layers 104 and 105 described later are omitted, and only a bit line BL and a contact electrode Ch and a contact electrode Vy described later are illustrated. FIG. 4 is a schematic sectional view illustrating a configuration of a portion of the semiconductor memory device, and illustrates the cross section of the structure illustrated in FIG. 3 cut along a line B-B′ and viewed in a direction of an arrow. FIG. 5 is a schematic sectional view illustrating a configuration of a portion of the semiconductor memory device, and illustrates an enlarged view of a part indicated by C in FIG. 4. Although FIG. 5 illustrates a YZ cross section, a structure similar to that of FIG. 5 is observed when observing a cross section (for example, an XZ cross section) other than the YZ cross section along the central axis of the semiconductor pillar 120. FIG. 6 is a schematic sectional view illustrating a configuration of a portion of the semiconductor memory device, and illustrates an XY cross section of the structure illustrated in FIG. 4 cut along a line D-D′ and viewed in a direction of an arrow. FIG. 6 illustrates an XY cross section at a height position corresponding to a conductive layer 110 (SGD) described later. FIG. 7 is a schematic sectional view illustrating a configuration of a portion of the semiconductor memory device, and illustrates an XY cross section of the structure illustrated in FIG. 4 cut along a line E-E′ and viewed in a direction of an arrow. FIG. 7 corresponds to an end region 124 of the semiconductor pillar 120 described later, and illustrates an XY cross section at a height position on the conductive layer 110 side (lower side) with respect to the contact electrode Ch described later.

As illustrated in FIG. 2, the semiconductor memory device according to the present embodiment includes a semiconductor substrate Sub. In the illustrated example, the semiconductor substrate Sub is provided with four memory cell array regions R_{MCA} arranged in the X and Y directions.

The memory cell array region R_{MCA} includes a plurality of finger structures FS arranged in the Y direction. The finger structure FS includes five string units SU arranged in the Y direction, as illustrated in FIG. 3. An inter-finger structure ST is provided between two adjacent finger structures FS in the Y direction. An inter-string unit insulating member SHE is provided between two adjacent string units SU in the Y direction.

In the present embodiment, one finger structure FS functions as the memory block BLK illustrated with reference to FIG. 1. Here, the plurality of finger structures FS may function as the memory block BLK. In addition, the finger structure FS may include two to four string units SU, or six or more.

Above the semiconductor substrate Sub, as illustrated in FIG. 4, there is an insulating layer 100 such as silicon oxide (SiO₂), and a conductive layer 112 provided on the upper surface thereof. Further, above the conductive layer 112, a plurality of finger structures FS and a plurality of inter-finger structures ST are provided, which are arranged alternately in the Y direction. Moreover, above the plurality of finger structures FS and the plurality of inter-finger structures ST, the insulating layer 104 such as silicon nitride (SiN) and the insulating layer 105 such as silicon oxide (SiO₂) are provided.

The finger structure FS is provided with a plurality of conductive layers 110 and an insulating layer 101 such as silicon oxide (SiO₂) arranged alternately in the Z direction, an insulating layer 102 such as silicon oxide (SiO₂) provided thereon, and a plurality of semiconductor pillars 120 extending in the Z direction through a portion of the insulating layer 102, the plurality of conductive layers 110, the plurality of insulating layers 101, and a portion of the conductive layer 112. In addition, a gate insulating film 130 is provided between the plurality of conductive layers 110 and the plurality of semiconductor pillars 120.

The conductive layer 110 is provided with a generally plate-like shape extending in the X direction. The conductive layer 110 may include a stacked film of a barrier conductive film 113 such as titanium nitride (TiN) and a metal film 114 such as tungsten (W), as illustrated in FIG. 5. The conductive layer 110 may also include polycrystalline silicon containing impurities such as phosphorus (P) or boron (B). Moreover, a high dielectric constant insulating film 103 may be provided on the upper and lower surfaces of the conductive layer 110 and on the surface facing the semiconductor pillar 120. The high dielectric constant insulating film 103 may be a metal oxide film such as aluminum oxide (AlO), hafnium oxide (HfO), or zirconium oxide (ZrO).

The plurality of conductive layers 110 function as the word lines WL and the gate electrodes of the plurality of memory cells MC connected thereto, as illustrated with reference to FIG. 1. In the following description, such a conductive layer 110 may be referred to as a conductive layer 110 (WL). The plurality of conductive layers 110 (WL) are electrically independent for each finger structure FS. The Y-direction positive side and the Y-direction negative side of the conductive layer 110 (WL) are electrically insulated from the structures in other finger structures FS via the inter-finger structure ST.

One or more conductive layers 110 located below the plurality of conductive layers 110 (WL) function as the source-side dummy word line DWS and the gate electrodes of the plurality of source-side dummy memory cells DMS connected thereto, as illustrated with reference to FIG. 1. In the following description, such a conductive layer 110 may be referred to as a conductive layer 110 (DWS). The conductive layer 110 (DWS) is configured in the same manner as the conductive layer 110 (WL).

One or more conductive layers 110 located below the plurality of conductive layers 110 (DWS) function as the source-side selection gate line SGS and the gate electrodes of the plurality of source-side select transistors STS connected thereto, as illustrated with reference to FIG. 1. In the following description, such conductive layer 110 may be referred to as a conductive layer 110 (SGS). The conductive layer 110 (SGS) is configured in the same manner as the conductive layer 110 (WL).

One or more conductive layers 110 located below the plurality of conductive layers 110 (SGS) function as the source-side selection gate line SGSB and the gate electrodes of the plurality of source-side select transistors STSB connected thereto, as illustrated with reference to FIG. 1. In the following description, such a conductive layer 110 may be referred to as a conductive layer 110 (SGSB). The conductive layer 110 (SGSB) is configured in the same manner as the conductive layer 110 (WL).

One or more conductive layers 110 located above the plurality of conductive layers 110 (WL) function as the drain-side dummy word line DWD and the gate electrodes of the plurality of drain-side dummy memory cells DMD connected thereto, as illustrated with reference to FIG. 1. In the following description, such a conductive layer 110 may be referred to as a conductive layer 110 (DWD). A portion of the conductive layer 110 (DWD) is configured in the same manner as the conductive layer 110 (WL). The other conductive layer 110 (DWD) provided above these conductive layers 110 (DWD) may basically be configured in the same manner as a conductive layer 110 (SGD) described later. However, the five parts of the conductive layer 110 (DWD) divided in the Y direction within one finger structure FS are electrically connected to each other.

One or more conductive layers 110 located above the plurality of conductive layers 110 (DWD) function as the drain-side selection gate line SGD and the gate electrodes of the plurality of drain-side select transistor STD connected thereto, as illustrated with reference to FIG. 1. In the following description, such a conductive layer 110 may be referred to as a conductive layer 110 (SGD).

As illustrated in FIG. 3, the conductive layer 110 (SGD) includes five parts divided in the Y direction by the inter-string unit insulating member SHE. The width Y_{SGD} in the Y direction of each of these five parts is smaller than a width Y_{WL} in the Y direction of the conductive layer 110 (WL). These five parts are electrically independent for each string unit SU. In each finger structure FS, the parts corresponding to the first and fifth string units SU counting from one side in the Y direction (for example, the negative side in the Y direction) are electrically insulated from the configurations in other finger structures FS via the inter-finger structures ST provided between the finger structures FS. In each finger structure FS, two adjacent parts in the Y direction are electrically insulated via the inter-string unit insulating member SHE.

One or more conductive layers 110 located above the plurality of conductive layers 110 (SGD) function as the drain-side selection gate line SGDT and the gate electrodes of the drain-side select transistors STDT connected thereto, as illustrated with reference to FIG. 1. In the following description, such a conductive layer 110 may be referred to as a conductive layer 110 (SGDT). The conductive layer 110 (SGDT) is basically configured similarly to the conductive layer 110 (SGD). However, the five parts of the conductive layer 110 (SGDT) divided in the Y direction within one finger structure FS are electrically connected to each other via contact electrodes (not shown).

The conductive layer 112 (FIG. 4) may include, for example, polycrystalline silicon containing impurities such as phosphorus (P) or boron (B). Also, on the lower side of the conductive layer 112, the conductive layer of, for example, a metal such as tungsten (W), tungsten silicide, or other conductive layers may be provided. The insulating layer 101 such as silicon oxide (SiO₂) is provided between the conductive layer 112 and the conductive layer 110.

The conductive layer 112 functions as the source line SL illustrated with reference to FIG. 1. The conductive layer 112 is commonly provided, for example, for all finger structures FS included in the memory cell array region R_{MCA} (FIG. 2).

The semiconductor pillars 120 are arranged in a specific pattern in the X and Y directions, as illustrated in FIG. 3. For example, the finger structure FS includes 20 semiconductor pillar arrays SC arranged from one side in the Y direction to the other side in the Y direction. Each of the 20 semiconductor pillar array rows SC includes a plurality of semiconductor pillars 120 arranged in the X direction.

Hereinafter, the semiconductor pillars 120 corresponding to the 4n-th (n is an integer of 1 or more and 4 or less) and 4n+1-th semiconductor pillar arrays SC counting from one side in the Y direction may be referred to as semiconductor pillars 120_{O}. Furthermore, the semiconductor pillars 120 corresponding to the first, second, third, 4n+2-th, 4n+3-th, and 20th semiconductor pillar arrays SC counting from one side in the Y direction may be referred to as semiconductor pillars 120_{I}.

The semiconductor pillar 120 includes, for example, polycrystalline silicon (Si). The semiconductor pillar 120 has a substantially cylindrical shape as illustrated in FIG. 4, and is provided with an insulating pillar 127 made of silicon oxide (SiO₂) in the center.

The semiconductor pillar 120 includes a region 121 provided below the lower surface of the lowermost conductive layer 110, a region 122 provided above the region 121 and below the lower end of the inter-string unit insulating member SHE, a region 123 provided above the region 122 and below the upper end of the insulating pillar 127, and an end region 124 provided above the region 123.

The region 121 includes the lower end of the semiconductor pillar 120. The region 121 contains N-type impurities such as phosphorus (P). The region 121 has a substantially cylindrical shape. The region 121 is connected to the conductive layer 112.

The region 122 faces a portion of the conductive layer 110 (SGSB), 110 (SGS), 110 (DWS), 110 (WL), and the conductive layer 110 (DWD). The region 122 functions as a channel region of the memory cell MC, the dummy memory cells (DMD and DMS), and the source-side select transistors STSB and STS illustrated with reference to FIG. 1. The region 122 does not need to contain N-type impurities such as phosphorus (P). The region 122 has a substantially cylindrical shape.

The region 123 faces a portion of the conductive layer 110 (DWD) and the conductive layers 110 (SGD) and 110 (SGDT). The region 123 functions as a channel region of the drain-side dummy memory cell DMD and the drain-side select transistors STD and STDT illustrated with reference to FIG. 1. The region 123 does not need to contain N-type impurities such as phosphorus (P).

The region 123 of the semiconductor pillar 120_{I} has a substantially cylindrical shape. On the other hand, the region 123 of the semiconductor pillar 120_{O} has a shape like a cylinder with a part missing (arc shape in XY cross section), as illustrated in FIG. 6.

The end region 124 (FIG. 4) is a region that includes the upper end of the semiconductor pillar 120 and is located above the uppermost conductive layer 110. The end region 124 contains N-type impurities such as phosphorus (P). The end region 124 is electrically connected to the bit line BL extending in the Y direction via the contact electrode Ch and the contact electrode Vy (FIG. 3) extending in the Z direction. The contact electrode Ch and the contact electrode Vy may include, for example, a stacked film of a barrier conductive film such as titanium nitride (TiN) and a metal film such as tungsten (W). The bit line BL may include, for example, a stacked film of a barrier conductive film such as titanium nitride (TiN) and a metal film such as copper (Cu).

The end region 124 of the semiconductor pillar 120_{I} has a substantially cylindrical columnar shape. On the other hand, the end region 124 of the semiconductor pillar 120_{O} has a shape like a cylindrical column with a part missing, as illustrated in FIG. 7.

The gate insulating film 130 includes a tunnel insulating film 131, a charge storage film 132, and a block insulating film 133 stacked between the semiconductor pillar 120 and the conductive layer 110, as illustrated in FIG. 5. The tunnel insulating film 131 and the block insulating film 133 include, for example, silicon oxide (SiO₂) or the like. The charge storage film 132 is a film capable of storing electric charges, such as silicon nitride (SiN).

The part of the gate insulating film 130 that is provided at a position corresponding to the region 121 of the semiconductor pillar 120 has a substantially cylindrical shape having a bottom, as illustrated in FIG. 4, and extends in the Z direction along the outer peripheral surface of the semiconductor pillar 120 except for the contact portion between the semiconductor pillar 120 and the conductive layer 112.

The part of the gate insulating film 130 that is provided at a position corresponding to the region 122 of the semiconductor pillar 120 has a substantially cylindrical shape and extends in the Z direction along the outer peripheral surface of the semiconductor pillar 120.

The part of the gate insulating film 130 that is provided at a position corresponding to the region 123 and the end region 124 of the semiconductor pillar 120_{I} has a substantially cylindrical shape and extends in the Z direction along the outer peripheral surface of the semiconductor pillar 120_{I}.

The part of the gate insulating film 130 that is provided at a position corresponding to the region 123 and the end region 124 of the semiconductor pillar 120_{O} has a shape that resembles a partially missing cylinder (arc shape in the XY cross section), as illustrated in FIGS. 6 and 7.

The inter-finger structure ST includes, for example, an inter-finger electrode 141 extending in the X-direction and the Z-direction, and an inter-finger insulating member 142, such as silicon oxide (SiO₂), provided on the side of the inter-finger electrode 141 in the Y-direction, as illustrated in FIGS. 3 and 4. The lower end of the inter-finger electrode 141 is connected to the conductive layer 112. An upper end position of the inter-finger electrode 141 is approximately aligned with the upper surface of position of the insulating layer 102. The inter-finger electrode 141 may include, for example, a stacked film of a barrier conductive film such as titanium nitride (TiN) and a metal film such as tungsten (W). The inter-finger electrode 141 may include, for example, polycrystalline silicon containing impurities such as phosphorus (P) or boron (B). The inter-finger electrode 141 functions as a portion of the source line SL illustrated with reference to FIG. 1. In addition, the inter-finger structure ST does not need to have the inter-finger electrode 141.

The inter-string unit insulating member SHE includes, for example, silicon oxide (SiO₂). As illustrated in FIG. 3, the inter-string unit insulating member SHE is provided between the 4n-th semiconductor pillar array SC and the 4n+1-th semiconductor pillar array SC counting from one side in the Y direction, and extends in the X direction.

In the illustrated example, the inter-string unit insulating member SHE is provided at a position overlapping a portion of the semiconductor pillar 120_{O}, and a portion of the tunnel insulating film 131, the charge storage film 132, and the block insulating film 133 constituting the gate insulating film 130, when viewed in the Z direction.

The inter-string unit insulating member SHE includes regions R1 and R2 as illustrated in FIG. 4. The region R1 extends in the Z direction in a height range corresponding to the plurality of conductive layers 110 (SGDT), 110 (SGD), and a portion of the conductive layer 110 (DWD), as well as the insulating layers 101 provided on the upper and lower surfaces of these conductive layers 110, and divides these configurations in the Y direction. In the illustrated example, the lower end of the region R1 is provided along the upper surface of one of the plurality of conductive layers 110 (DWD). The region R2 extends in the Z direction in a height range corresponding to the insulating layer 102 and divides the insulating layer 102 in the Y direction.

A width Y_{R1} of the region R1 in the Y direction may be approximately constant, or may gradually decrease from the upper side to the lower side. In the illustrated example, the width Y_{R1} of the region R1 in the Y direction at a height position corresponding to the plurality of conductive layers 110 (SGDT) and 110 (SGD), and a portion of the conductive layer 110 (DWD) is approximately equal to the width Y_{R1} of the region R1 in the Y direction at a height position corresponding to the insulating layers 101 provided on the upper and lower surfaces of these conductive layers 110. The width Y_{R2} of the region R2 in the Y direction may be approximately constant, or may gradually decrease from the upper side to the lower side. The width Y_{R1} of the region R1 in the Y direction is larger than the width Y_{R2} of the region R2 in the Y direction.

The width Y_{R1} of the region R1 in the Y direction may be, for example, as illustrated in FIG. 6, the distance in the Y direction between two portions of the conductive layers 110 (SGDT) and 110 (SGD), and a portion of the conductive layer 110 (DWD), or the insulating layer 101 provided on the upper and lower surfaces of these conductive layers 110, which are divided in the Y direction by the inter-string unit insulating member SHE.

In addition, in the height range corresponding to the region R1, as illustrated in FIG. 6, of two semiconductor pillar arrays SC adjacent in the Y direction with the inter-string unit insulating member SHE interposed therebetween, the distance in the Y direction from the end of the plurality of semiconductor pillars 120 included in one row on the inter-string unit insulating member SHE side to the end of the plurality of semiconductor pillars 120 included in the other row on the inter-string unit insulating member SHE side is approximately equal to the width Y_{R1} and is larger than the width Y_{R2}.

Similarly, of two semiconductor pillar arrays SC adjacent in the Y direction with the inter-string unit insulating member SHE interposed therebetween, the distance in the Y direction from the end of the plurality of gate insulating films 130 corresponding to the plurality of semiconductor pillars 120 included in one row on the inter-string unit insulating member SHE side to the end of the plurality of gate insulating films 130 corresponding to the plurality of semiconductor pillars 120 included in the other row on the inter-string unit insulating member SHE side is approximately equal to the width Y_{R1} and is larger than the width Y_{R2}.

For example, of two semiconductor pillar arrays SC adjacent in the Y direction with the inter-string unit insulating member SHE interposed therebetween, the distance in the Y direction from the end of the plurality of charge storage films 132 corresponding to the plurality of semiconductor pillars 120 included in one row on the inter-string unit insulating member SHE side to the end of the plurality of charge storage films 132 corresponding to the plurality of semiconductor pillars 120 included in the other row on the inter-string unit insulating member SHE side is approximately equal to the width Y_{R1} and is larger than the width Y_{R2}.

In addition, of two semiconductor pillar arrays SC adjacent in the Y direction with the inter-string unit insulating member SHE interposed therebetween, the distance in the Y direction from the end of the plurality of high dielectric constant insulating films 103 corresponding to the plurality of semiconductor pillars 120 included in one row on the inter-string unit insulating member SHE side to the end of the plurality of high dielectric constant insulating films 103 corresponding to the plurality of semiconductor pillars 120 included in the other row on the inter-string unit insulating member SHE side is approximately equal to the width Y_{R1} and is larger than the width Y_{R2}.

As illustrated in FIG. 7, the width Y_{R2} of the region R2 in the Y direction may be a distance, of two semiconductor pillar arrays SC adjacent in the Y direction with the inter-string unit insulating member SHE interposed therebetween, in the Y direction from the surface of the end region 124 of the plurality of semiconductor pillars 120 included in one row on the inter-string unit insulating member SHE side to the surface of the end region 124 of the plurality of semiconductor pillars 120 included in the other row on the inter-string unit insulating member SHE side.

In addition, in the height range corresponding to the region R2, as illustrated in FIG. 7, of two semiconductor pillar arrays SC adjacent in the Y direction with the inter-string unit insulating member SHE interposed therebetween, the distance in the Y direction from the end of the plurality of gate insulating films 130 corresponding to the plurality of semiconductor pillars 120 included in one row on the inter-string unit insulating member SHE side to the end of the plurality of gate insulating films 130 corresponding to the plurality of semiconductor pillars 120 included in the other row on the inter-string unit insulating member SHE side is approximately equal to the width Y_{R2} and is smaller than the width Y_{R1}.

A void V is formed inside the region R1. In the example of FIG. 4, the void V extends in the Z direction in a height range corresponding to the plurality of conductive layers 110 (SGDT) and 110 (SGD), and a portion of the conductive layer 110 (DWD), as well as the insulating layers 101 provided on the upper and lower surfaces of these conductive layers 110. In addition, the inter-string unit insulating member SHE does not need to include the void V inside the region R1.

### Manufacturing Method

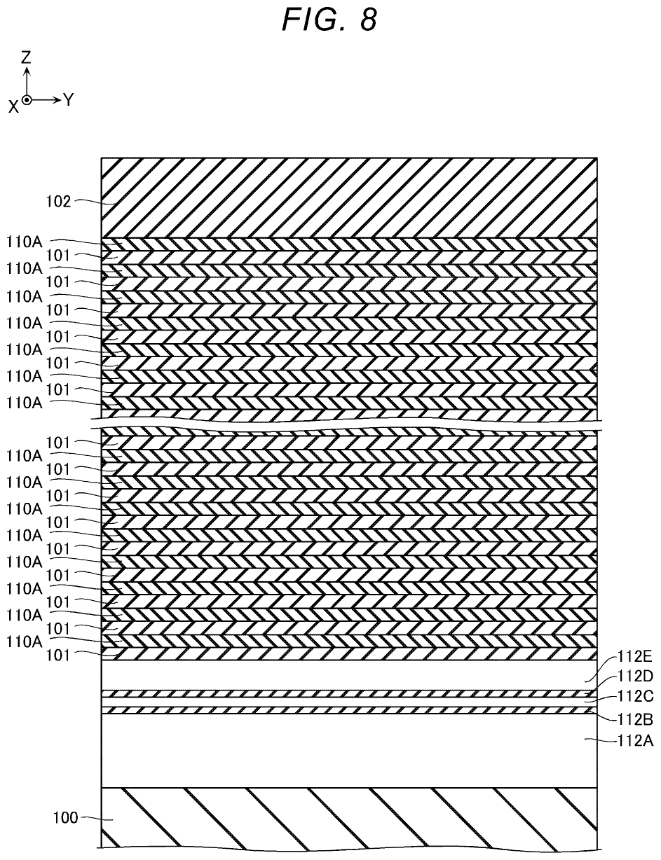

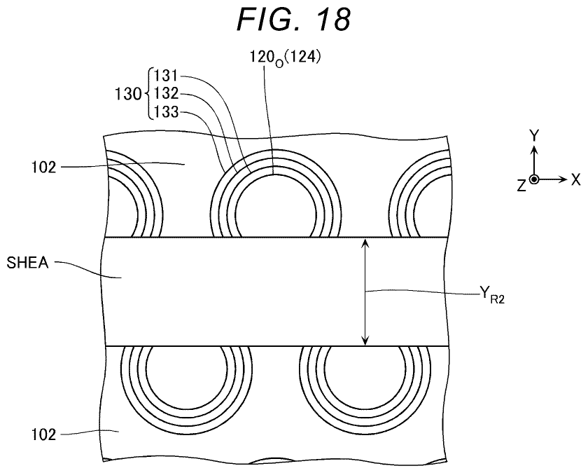

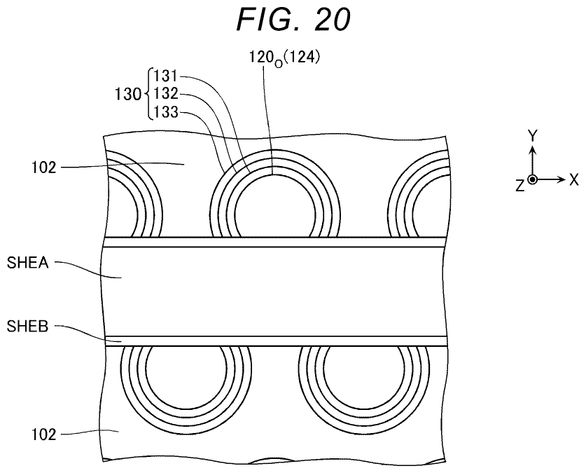

Next, a method for manufacturing a semiconductor memory device according to the first embodiment will be illustrated with reference to FIGS. 8 to 32. FIGS. 8 to 17, 19, 21, 23, 25, and 28 to 32 are schematic sectional views illustrating the same manufacturing method, and illustrate cross sections corresponding to FIG. 4. FIGS. 18 and 20 are schematic sectional views illustrating the same manufacturing method, and illustrate cross sections corresponding to FIG. 7. FIGS. 22, 24, 26, and 27 are schematic sectional views illustrating the same manufacturing method, and illustrate cross sections corresponding to FIG. 6.

In method for manufacturing the semiconductor memory device according to the present embodiment, for example, as illustrated in FIG. 8, the insulating layer 100 is formed above the semiconductor substrate (not shown). Next, on the insulating layer 100, a semiconductor layer 112A such as silicon, a sacrificial layer 112B such as silicon oxide, a sacrificial layer 112C such as silicon, a sacrificial layer 112D such as silicon oxide, and a semiconductor layer 112E such as silicon are formed. Also, the plurality of insulating layers 101 and the plurality of sacrificial layers 110A are alternately formed. In addition, a portion of the insulating layer 102 is formed. This process is carried out by a method such as chemical vapor deposition (CVD).

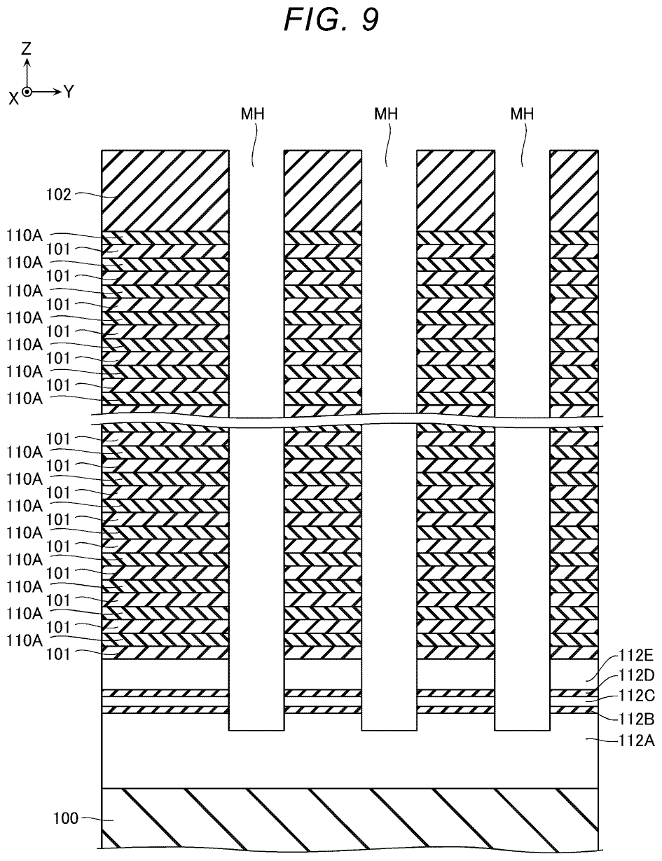

Next, as illustrated in FIG. 9, a memory hole MH is formed at a position corresponding to the semiconductor pillar 120. The memory hole MH extends in the Z direction, penetrates the insulating layer 102, the insulating layer 101, the sacrificial layer 110A, the semiconductor layer 112E, the sacrificial layer 112D, the sacrificial layer 112C, and the sacrificial layer 112B, and exposes the upper surface of the semiconductor layer 112A. This process is carried out by a method such as reactive ion etching (RIE).

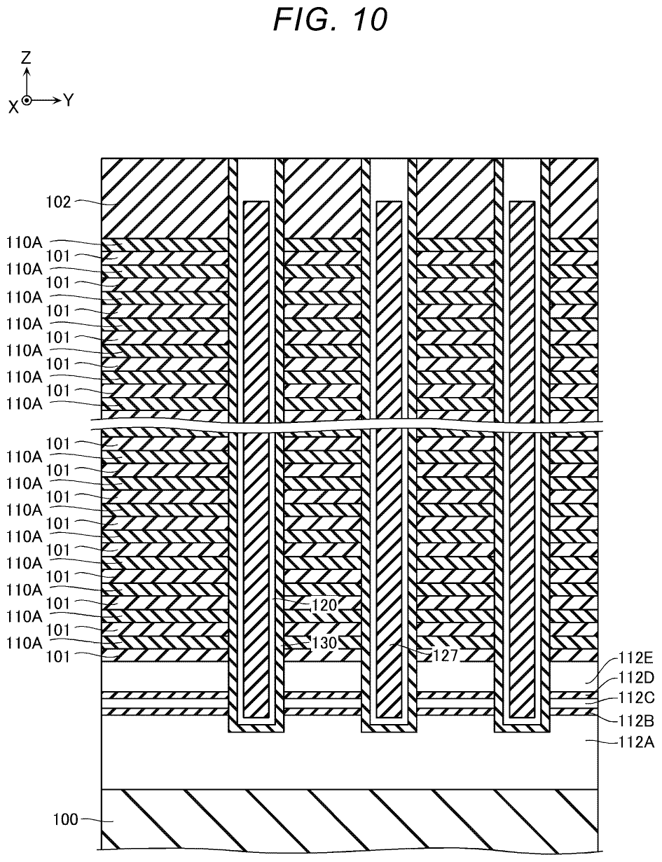

Next, as illustrated in FIG. 10, the gate insulating film 130, the semiconductor pillar 120, and the insulating pillar 127 are formed inside the memory hole MH. This process is carried out by a method such as CVD.

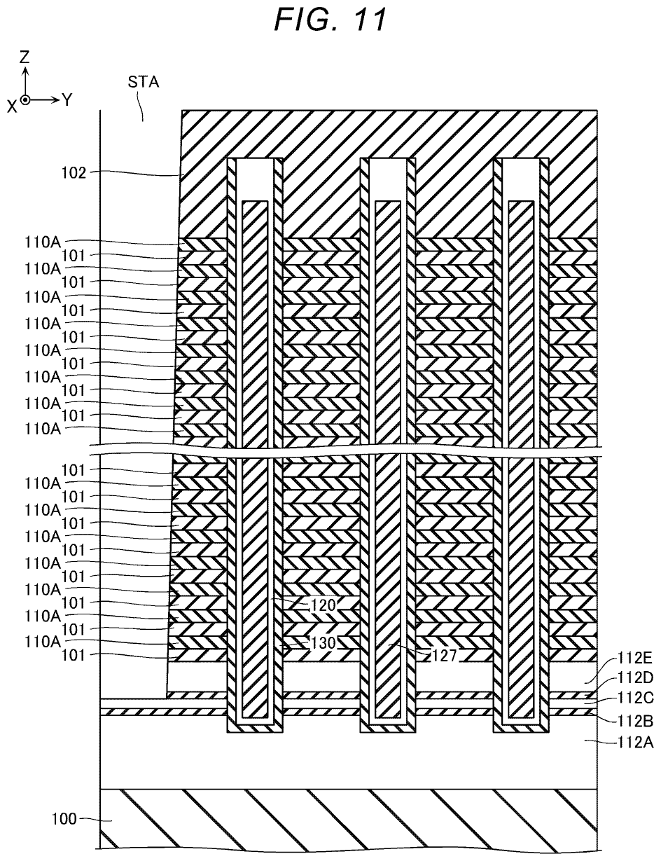

Next, as illustrated in FIG. 11, a portion of the insulating layer 102 is formed by a method such as CVD. In addition, a groove STA is formed at the position corresponding to the inter-finger structure ST. The groove STA extends in the Z direction and the X direction, divides the insulating layer 102, the insulating layer 101, the sacrificial layer 110A, the semiconductor layer 112E, and the sacrificial layer 112D in the Y direction, and exposes the upper surface of the sacrificial layer 112C. This process is carried out by a method such as RIE.

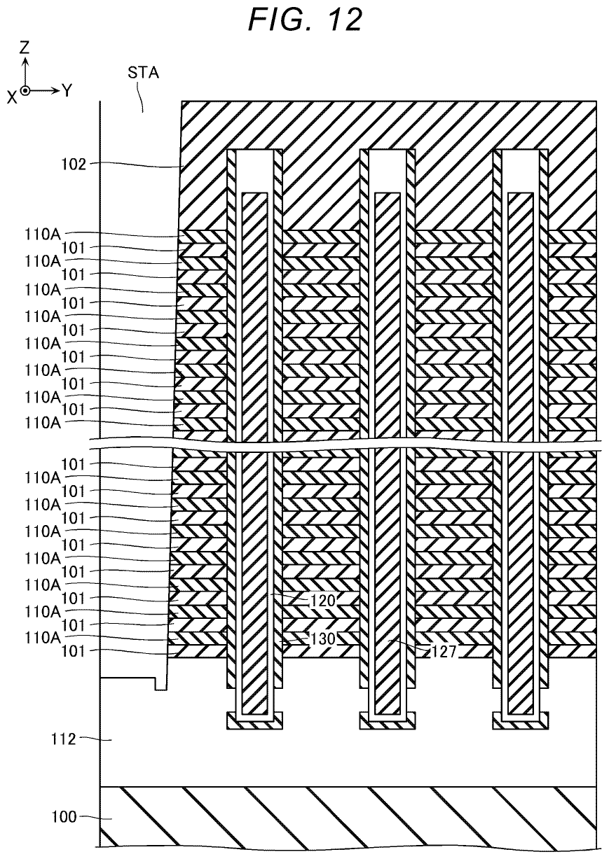

Next, as illustrated in FIG. 12, the sacrificial layer 112B, the sacrificial layer 112C, the sacrificial layer 112D, and a portion of the gate insulating film 130 are removed to form the conductive layer 112. The sacrificial layers 112B, 112C, and 112D, and a portion of the gate insulating film 130 are removed by, for example, wet etching or the like. The conductive layer 112 is formed by a method such as epitaxial growth.

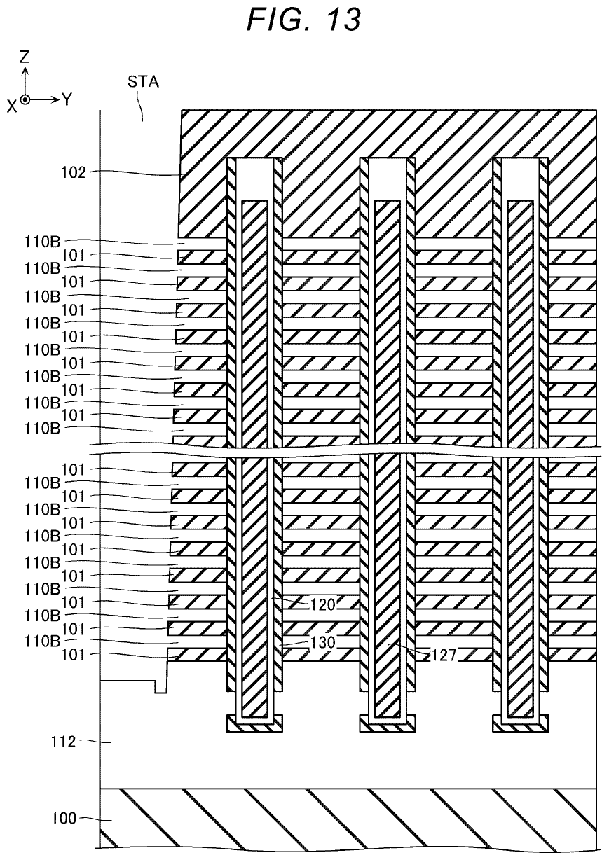

Next, as illustrated in FIG. 13, the sacrificial layer 110A is removed via the groove STA to form a plurality of voids 110B aligned in the Z direction. This forms a hollow structure including the plurality of insulating layers 101 and 102 aligned in the Z direction and the structures inside the memory hole MH that support them (semiconductor pillar 120, gate insulating film 130, and insulating pillar 127). This process is carried out by a method such as wet etching.

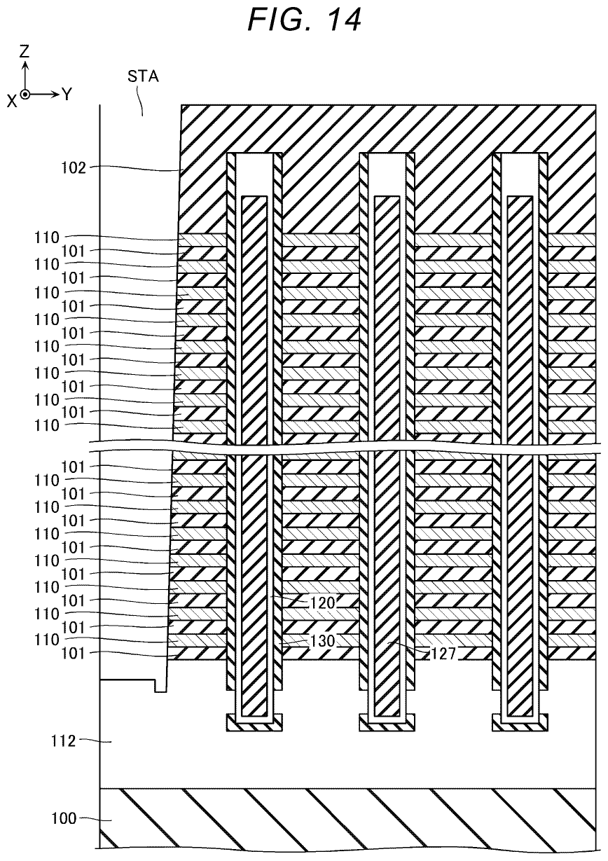

Next, as illustrated in FIG. 14, the conductive layer 110 is formed in the void 110B. This process is carried out by a method such as CVD.

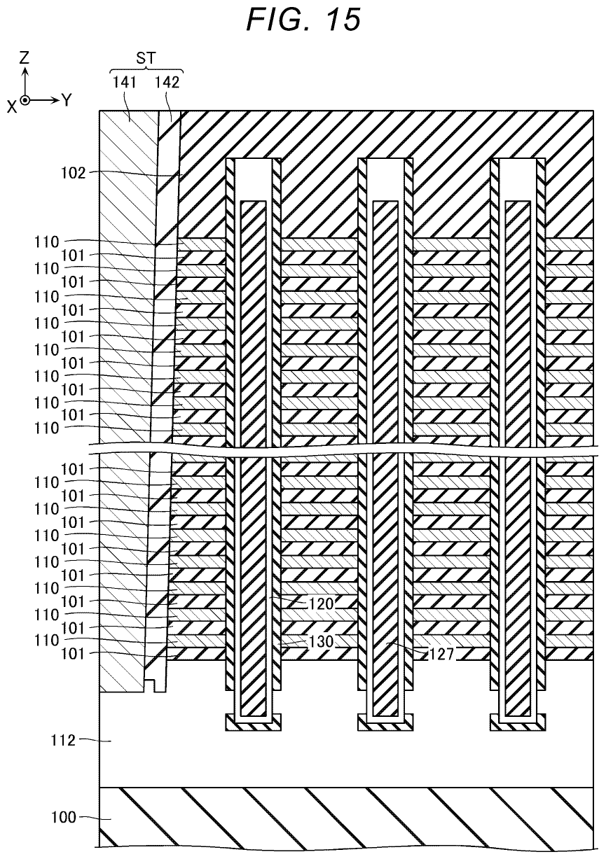

Next, as illustrated in FIG. 15, the inter-finger structure ST is formed in the groove STA. This process is carried out by methods such as CVD and RIE.

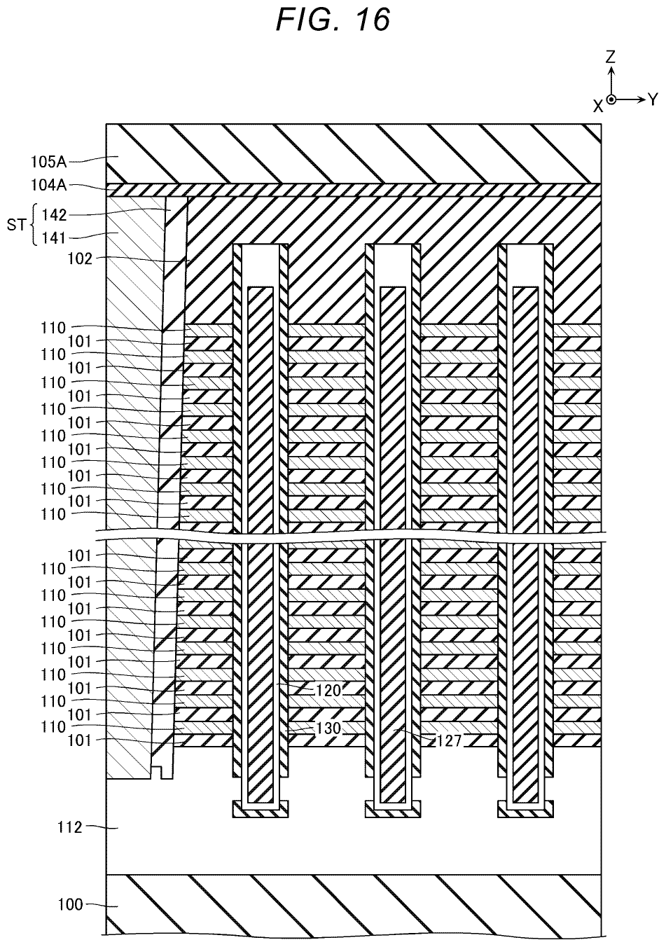

Next, as illustrated in FIG. 16, for example, an insulating layer 104A such as silicon nitride (SiN) and an insulating layer 105A such as silicon oxide (SiO₂) are formed on the upper surface of the insulating layer 102 and the inter-finger structure ST. This process is carried out by a method such as CVD.

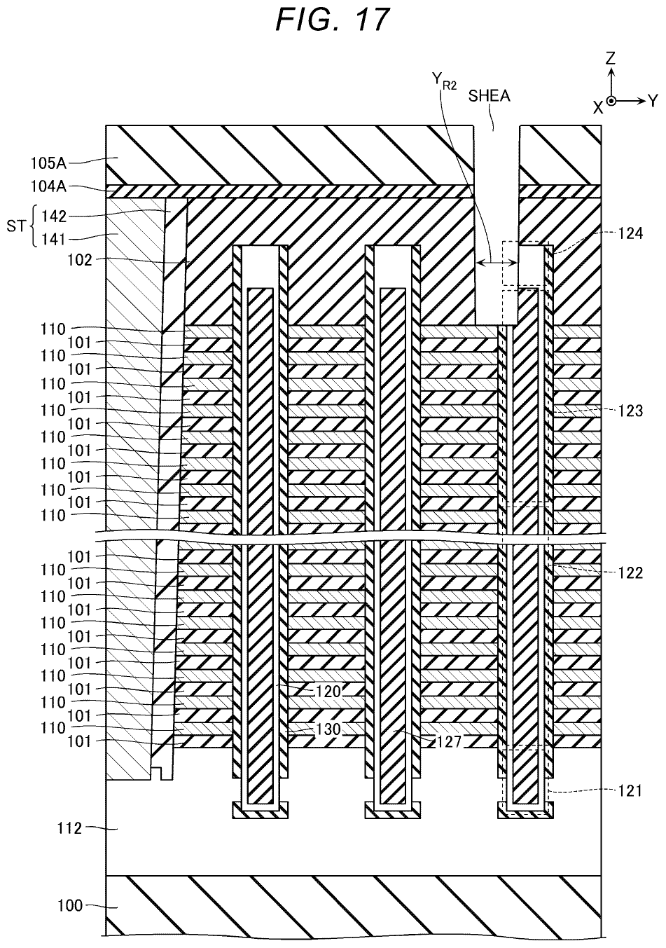

Next, as illustrated in FIGS. 17 and 18, a groove SHEA is formed at a position corresponding to the inter-string unit insulating member SHE. The groove SHEA extends in the Z direction and the X direction, divides the insulating layer 102 in the Y direction, and exposes the upper surface of the uppermost conductive layer 110, as well as a portion of the semiconductor pillar 120, the gate insulating film 130, and the insulating pillar 127. This process is carried out by a method such as RIE.

In the example of FIGS. 17 and 18, the width of the groove SHEA in the Y direction at the height position corresponding to the end region 124 of the semiconductor pillar 120 is approximately equal to the width Y_{R2} illustrated with reference to FIGS. 4 and 7.

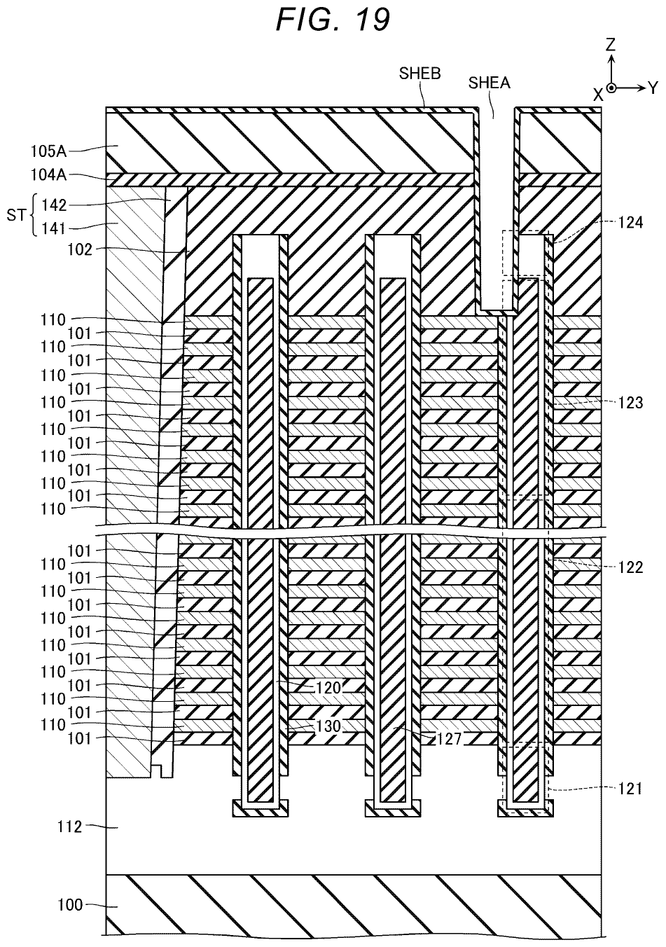

Next, as illustrated in FIGS. 19 and 20, a protective film SHEB is formed on the bottom and inner wall surfaces of the groove SHEA and on the upper surface of the insulating layer 105A. The protective film SHEB contains, for example, carbon (C). This process is carried out by a method such as CVD. The protective film SHEB is formed thin enough not to fill the groove SHEA.

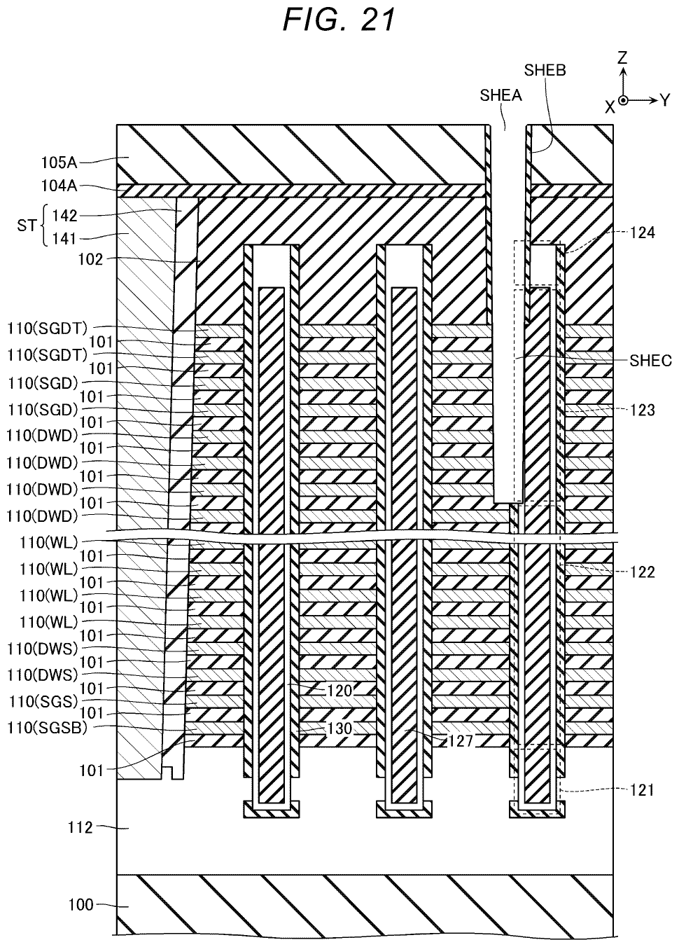

Next, as illustrated in FIGS. 21 and 22, the part of the protective film SHEB formed on the bottom surface of the groove SHEA is removed, and then the groove SHEC is formed. The groove SHEC extends in the Z direction and the X direction, and divides the plurality of conductive layers 110 (SGDT) and 110 (SGD), and a portion of the conductive layer 110 (DWD), and the insulating layer 101 provided between them in the Y direction. This process is carried out by a method such as RIE.

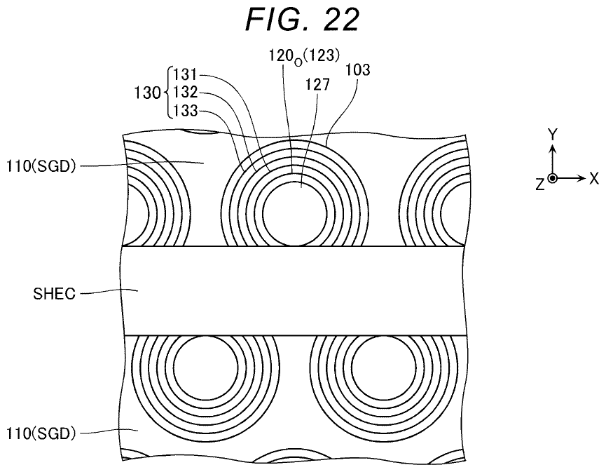

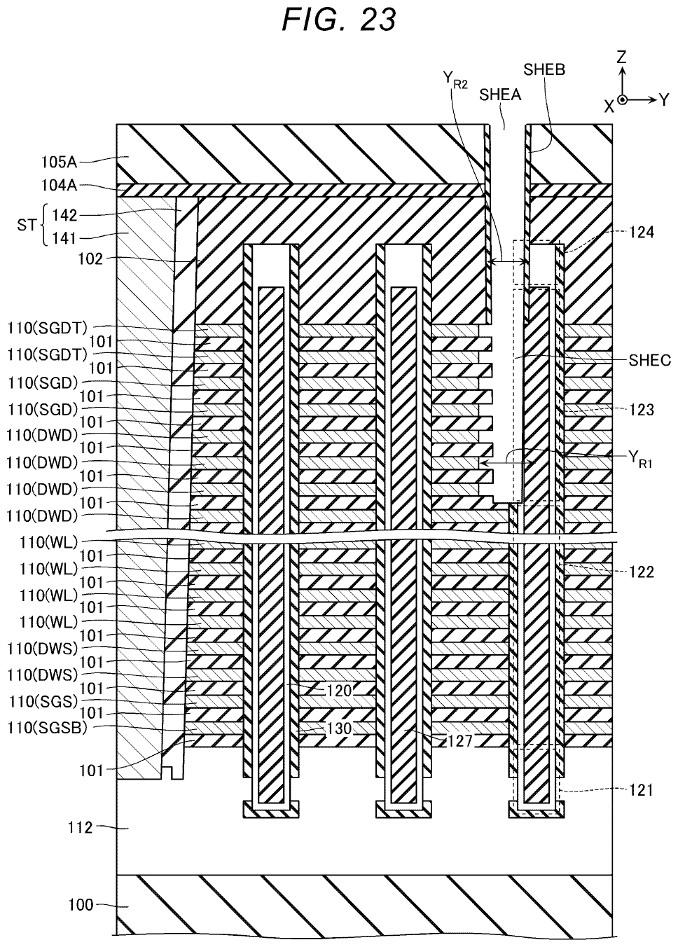

Next, as illustrated in, for example, FIGS. 23 and 24, a portion of the conductive layer 110 is removed via the groove SHEC, and the width of the groove SHEC in the Y direction is increased at a height position corresponding to the portion of the conductive layer 110. This process is carried out by a method such as wet etching. In the example of FIG. 24, in addition to the conductive layer 110, a portion of the high dielectric constant insulating film 103 is also removed.

In this process, the width of the groove SHEC in the Y direction at the height position corresponding to the plurality of conductive layers 110 (SGDT) and 110 (SGD) and a portion of the conductive layer 110 (DWD) becomes larger than the width in the Y direction of the groove SHEC at the height position corresponding to the insulating layer 101 provided on the upper and lower surfaces of these conductive layers 110. For example, at the height position corresponding to the conductive layer 110 (SGD), the width of the groove SHEC in the Y direction is approximately equal to the width Y_{R1} illustrated with reference to FIGS. 4 and 6.

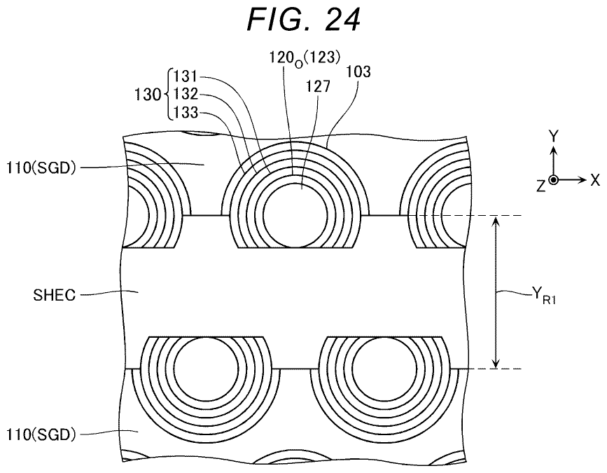

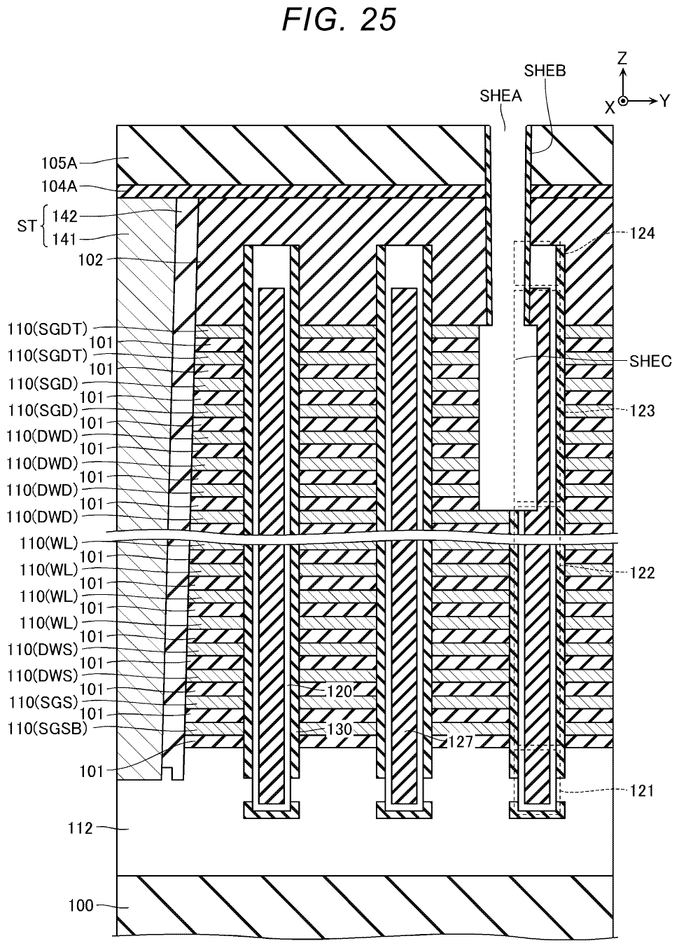

Next, as illustrated in, for example, FIGS. 25 and 26, a portion of the insulating layer 101 is removed and the width of the groove SHEC in the Y direction is increased at a height position corresponding to the insulating layer 101. This process is carried out by a method such as wet etching. In the present embodiment, the insulating layer 101, the insulating pillar 127, the tunnel insulating film 131, and the block insulating film 133 are formed of silicon oxide (SiO₂). Therefore, when a portion of the insulating layer 101 is removed, as illustrated in FIG. 26, a portion of the insulating pillar 127, a portion of the tunnel insulating film 131, and a portion of the block insulating film 133 are also removed.

In this process, the width of the groove SHEC in the Y direction at the height position corresponding to the plurality of conductive layers 110 (SGDT), 110 (SGD) and a portion of the conductive layer 110 (DWD) is approximately equal to the width of the groove SHEC in the Y direction at the height position corresponding to the insulating layers 101 provided on the upper and lower surfaces of these conductive layers 110. For example, at the height position corresponding to the insulating layer 101 provided on the upper and lower surfaces of the conductive layer 110 (SGD), the width of the groove SHEC in the Y direction is approximately equal to the width Y_{R1} illustrated with reference to FIGS. 4 and 6.

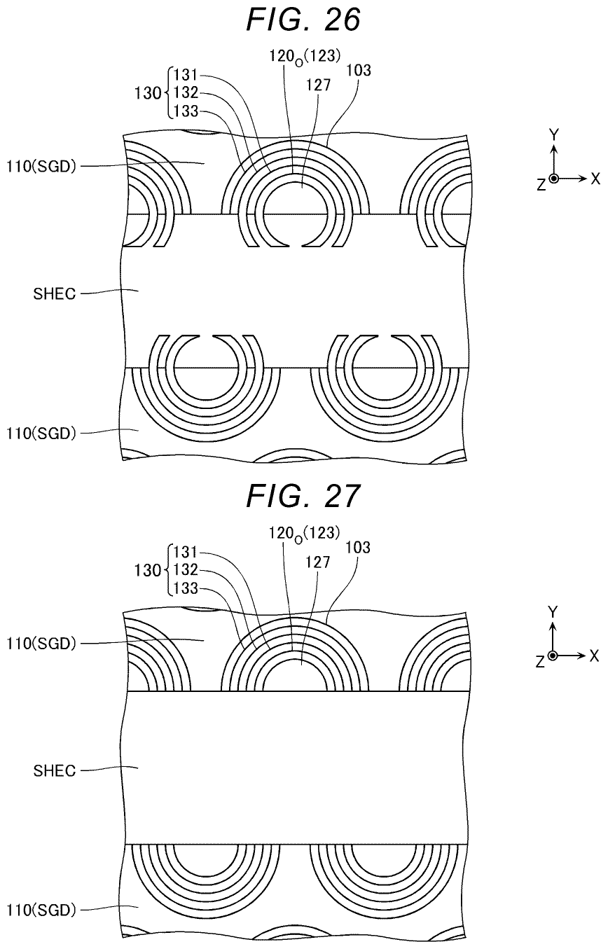

Next, as illustrated in FIG. 27, a portion of the semiconductor pillar 120 and the charge storage film 132 are removed via the groove SHEC. This process is carried out by a method such as wet etching.

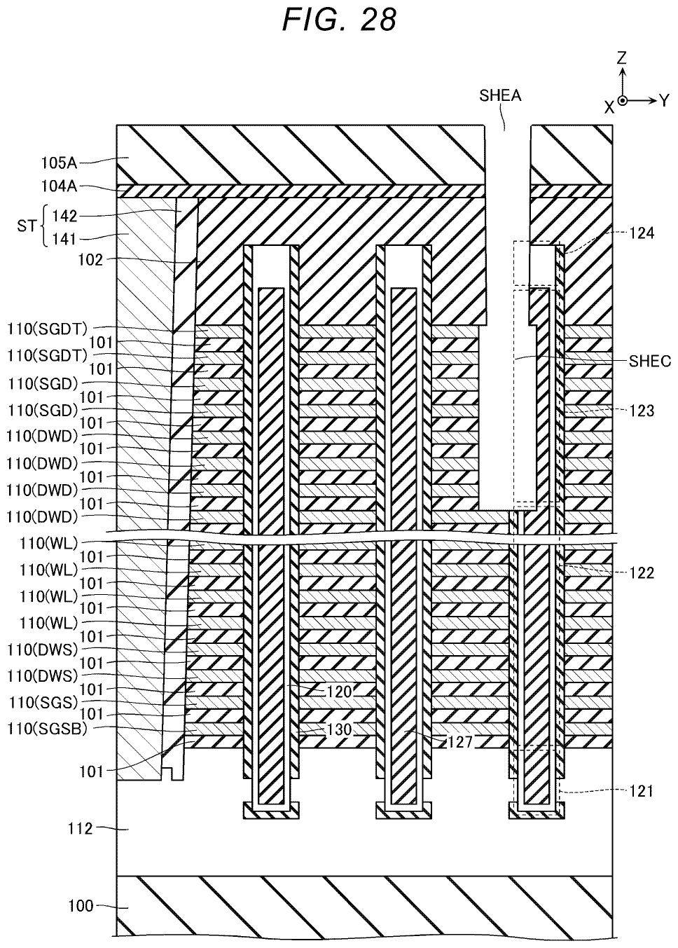

Next, the protective film SHEB is removed, for example as illustrated in FIG. 28. This process is carried out by a method such as ashing.

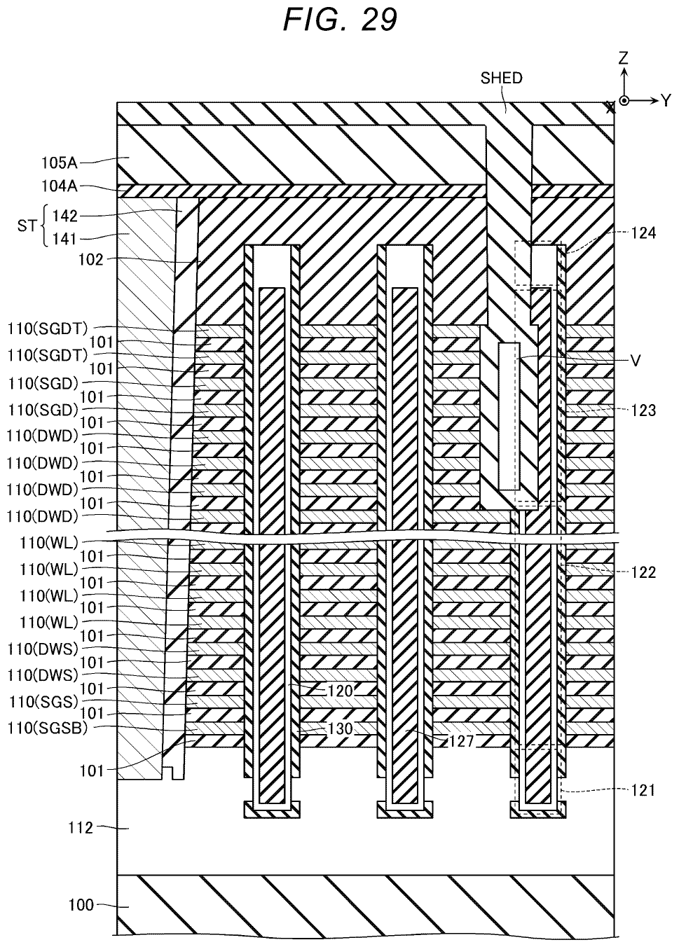

Next, as illustrated in FIG. 29, for example, an insulating member SHED is formed inside the grooves SHEA and SHEC and on the upper surface of the insulating layer 105A. A part formed inside the groove SHEC, of the insulating member SHED, becomes the region R1 of the inter-string unit insulating member SHE. A part formed inside the groove SHEA, of the insulating member SHED, becomes the region R2 of the inter-string unit insulating member SHE. This process is carried out by a method such as CVD.

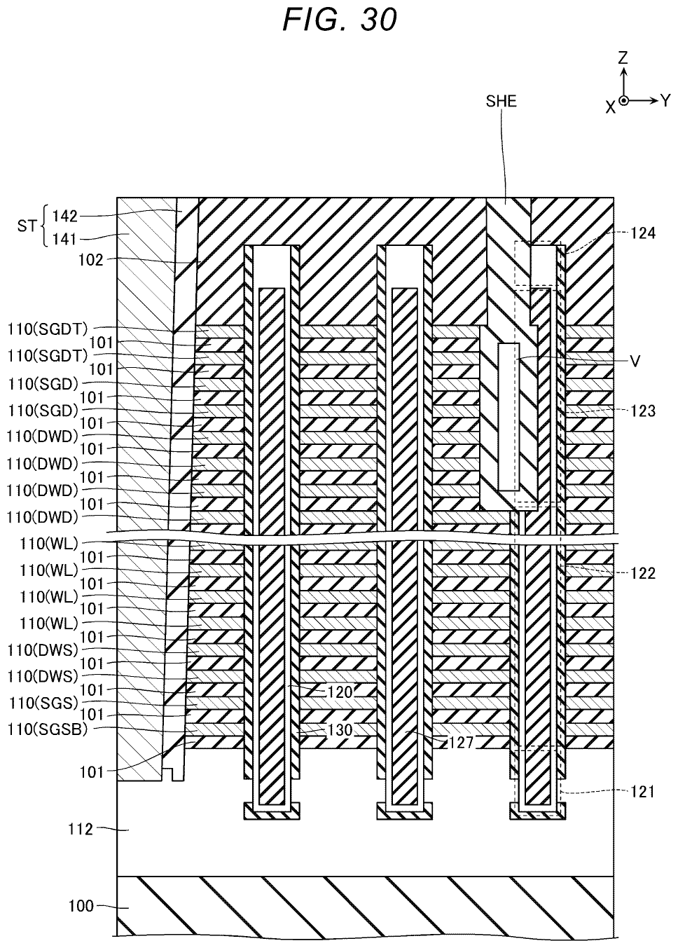

Next, as illustrated in FIG. 30, for example, the insulating layers 104A and 105A, and a portion of the insulating member SHED are removed to expose the upper surfaces of the insulating layer 102 and the inter-finger structure ST, and an inter-string unit insulating member SHE is formed. This process is carried out by a method such as chemical mechanical polishing (CMP).

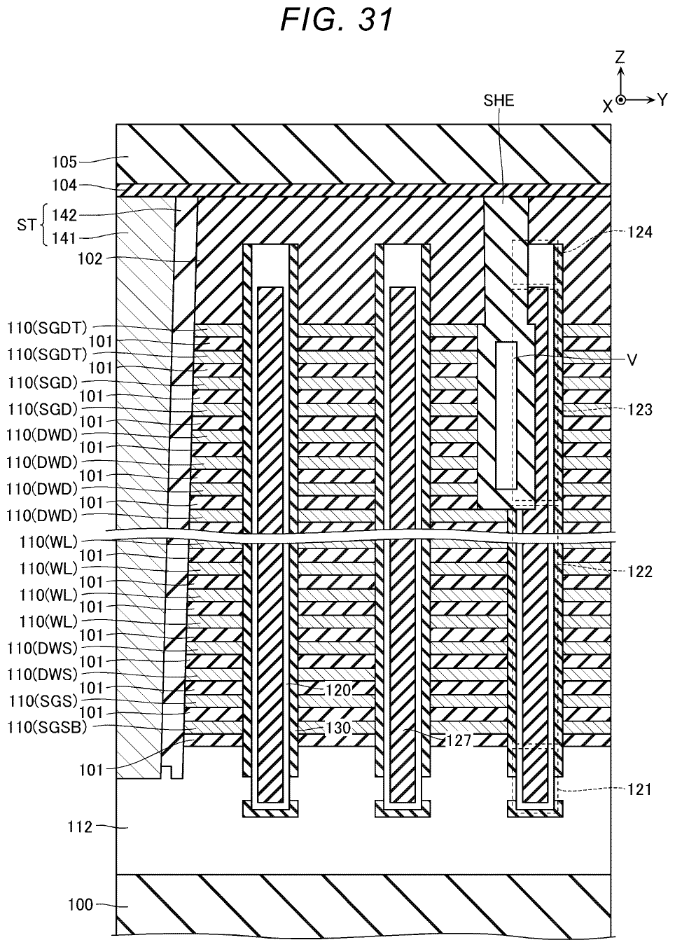

Next, as illustrated in FIG. 31, the insulating layers 104 and 105 are formed on the upper surface of insulating layer 102. This process is carried out by a method such as CVD.

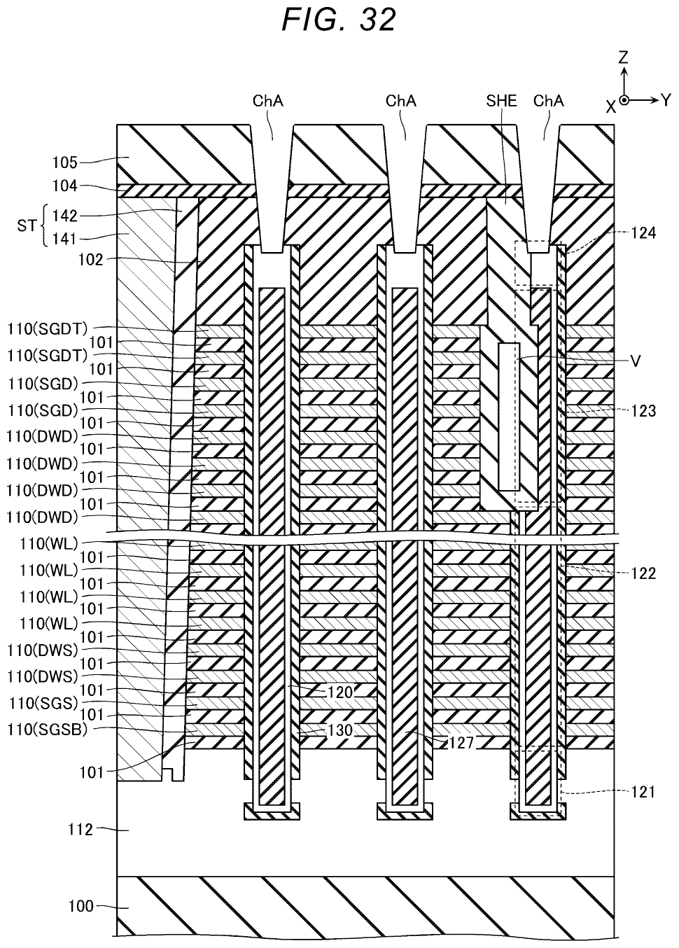

Next, as illustrated in FIG. 32, a contact hole ChA is formed at a position corresponding to the contact electrode Ch. The contact hole ChA extends in the Z direction, penetrates the insulating layers 105 and 104 and a portion of the insulating layer 102, and exposes the upper end of the semiconductor pillar 120. This process is carried out by a method such as RIE.

After that, the contact electrode Ch is formed, and the structure as illustrated with reference to FIG. 4 is formed.

### Effects

As illustrated with reference to FIG. 3 and the like, in the semiconductor memory device according to the first embodiment, the conductive layer 110 (SGD) and the like are divided into a plurality of parts by the inter-string unit insulating member SHE. In the semiconductor memory device according to the first embodiment, the inter-string unit insulating member SHE is provided between the 4n-th semiconductor pillar array SC and the 4n+1-th semiconductor pillar array SC counting from one side in the Y direction.

With this configuration, all of the semiconductor pillars 120 in the semiconductor pillar array SC can be used as memory cells MC, or the like. Therefore, for example, compared to a structure in which a portion of the semiconductor pillars 120 provided at a position overlapping with the inter-string unit insulating member SHE is used as a dummy, and it is not used as a memory cell MC or the like, it is possible to achieve a high degree of integration of the semiconductor memory device.

Here, in the first embodiment, the semiconductor pillar 120 is basically surrounded by the conductive layer 110 all around. On the other hand, as illustrated in FIG. 6 or the like, the region 123 of the semiconductor pillar 120_{O} is not entirely surrounded by the conductive layer 110, and the end in the Y direction faces another conductive layer 110 via the inter-string unit insulating member SHE. In such a configuration, the semiconductor pillar 120_{O} provided on one side in the Y direction with respect to the inter-string unit insulating member SHE is affected by the electric field from the conductive layer 110 (SGD) provided on the other side in the Y direction with respect to the inter-string unit insulating member SHE.

For example, when selecting the string unit SU provided on the other side in the Y direction with respect to the inter-string unit insulating member SHE, a voltage smaller than a threshold voltage of the drain-side select transistor STD is supplied to the conductive layer 110 (SGD) provided on one side in the Y direction, and a region in which an inversion layer (channel) is not formed is generated in the semiconductor pillar 120, thereby electrically dividing the bit line BL and the memory cell MC. Moreover, a voltage larger than the threshold voltage of the drain-side select transistor STD is supplied to the conductive layer 110 (SGD) provided on the other side in the Y direction, forming the inversion layer (channel) in the semiconductor pillar 120, thereby making the bit line BL and the memory cell MC conductive. In such an operation, there is a risk that the inversion layer (channel) may be formed at the end of the region 123 in the Y direction of the semiconductor pillar 120_{O} provided on one side in the Y direction due to an electric field from the conductive layer 110 (SGD) provided on the other side in the Y direction, and the drain-side select transistor STD, which is supposed to be in the OFF state, may be in the ON state.

In order to minimize such a phenomenon, it is possible to increase the width of the inter-string unit insulating member SHE in the Y direction, for example. However, if the width of the inter-string unit insulating member SHE in the Y direction is increased, it becomes difficult to position the contact hole ChA and the end region 124 of the semiconductor pillar 120 in the process illustrated with reference to FIG. 32. For example, if the end region 124 is not exposed inside the contact hole ChA, an open defect may occur in which the contact electrode Ch does not come into contact with the semiconductor pillar 120. Furthermore, for example, if the conductive layer 110 is exposed inside the contact hole ChA, a short circuit defect may occur in which the contact electrode Ch comes into contact with the conductive layer 110. Therefore, if the width of the inter-string unit insulating member SHE in the Y direction is increased, yield will decrease.

Therefore, in the present embodiment, as illustrated with reference to FIGS. 23 and 24, a portion of the conductive layer 110 (SGD) is removed while the end region 124 of the semiconductor pillar 120 is protected, and the width of the groove SHEC in the Y direction is increased at a height position corresponding to the conductive layer 110 (SGD). According to this method, it is possible to provide a semiconductor memory device that operates properly without causing a decrease in the yield.

In the present embodiment, in the process illustrated with reference to FIGS. 25 and 26, a portion of the insulating layer 101 is removed via the groove SHEC, and the width of the groove SHEC in the Y direction is increased at a height position corresponding to the insulating layer 101. According to this method, it is possible to make the inner wall surface of the groove SHEC relatively flat, and it is possible to preferably form the insulating member SHED in the process illustrated with reference to FIG. 29.

In the present embodiment, in the process illustrated with reference to FIG. 27, a portion of the semiconductor pillar 120 is removed via the groove SHEC. According to this method, the distance between the semiconductor pillar 120_{O} provided on one side in the Y direction with respect to the inter-string unit insulating member SHE and the conductive layer 110 (SGD) provided on the other side in the Y direction with respect to the inter-string unit insulating member SHE is further increased, so that it is possible to provide a semiconductor memory device that operates more favorably.

Moreover, it is desirable that the charge storage film 132 and the high dielectric constant insulating film 103 are covered by the conductive layer 110 in the XY cross section corresponding to any one of the conductive layers 110. This is because, when the charge storage film 132 and the high dielectric constant insulating film 103 have parts spaced apart from the conductive layer 110, charges may be stored in such parts, making it difficult to adjust the threshold voltage of the drain-side select transistor STD, and the like.

Therefore, in the present embodiment, in the process illustrated with reference to FIG. 24, a portion of the high dielectric constant insulating film 103 is removed via the groove SHEC. In the process illustrated with reference to FIG. 27, a portion of the charge storage film 132 is removed via the groove SHEC. According to this method, it is possible to provide a semiconductor memory device that can minimize the above-described charge accumulation and operate more favorably.

In the process illustrated with reference to FIG. 24 and the process illustrated with reference to FIG. 27, a portion of the semiconductor pillar 120, a portion of the charge storage film 132, and a portion of the high dielectric constant insulating film 103 are removed via the groove SHEC, so that the inner wall surface of the groove SHEC can be made relatively flat. Therefore, the insulating member SHED can be suitably formed in the process illustrated with reference to FIG. 29.

In the first embodiment, at least one of the processes of removing a portion of the high dielectric constant insulating film 103 via the groove SHEC (FIG. 24), removing a portion of the semiconductor pillar 120 via the groove SHEC (FIG. 27), and removing a portion of the charge storage film 132 via the groove SHEC (FIG. 27) may be omitted. This makes it possible to reduce the number of manufacturing processes.

### Second Embodiment

In the method for manufacturing the semiconductor memory device according to the first embodiment, a portion of the insulating layer 101 is removed in the process illustrated with reference to FIGS. 25 and 26. However, this process may be omitted. Hereinafter, a configuration manufactured by omitting this process will be exemplified as a semiconductor memory device according to the second embodiment.

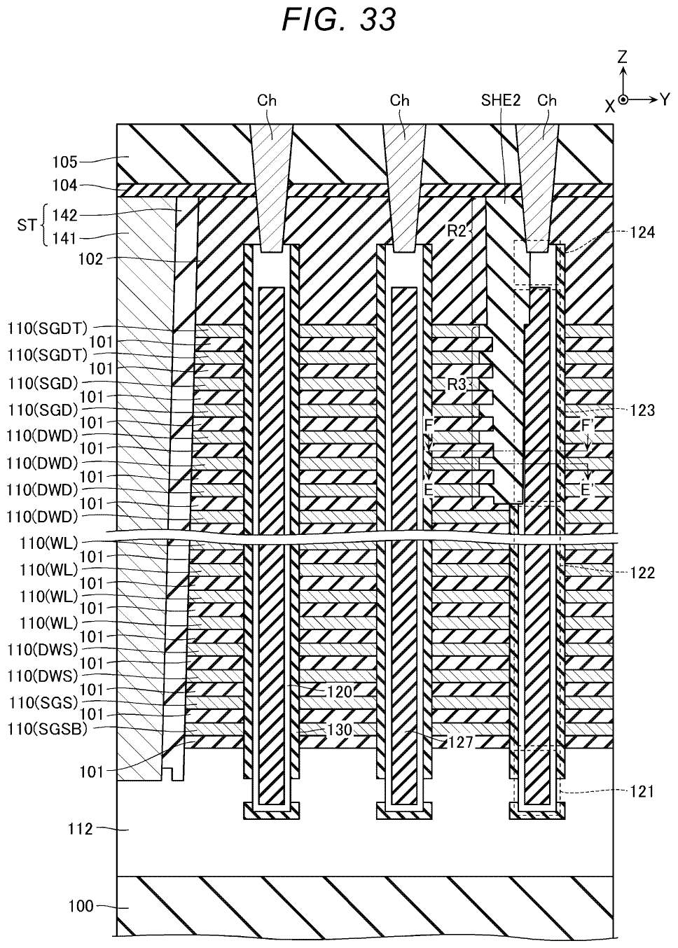

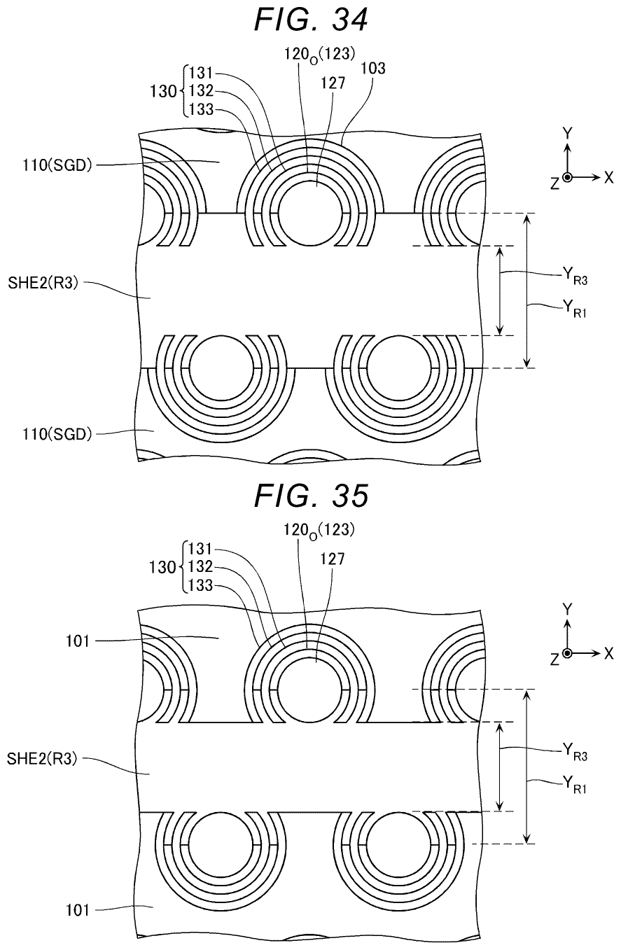

FIG. 33 is a schematic sectional view illustrating a configuration of a portion of a semiconductor memory device according to a second embodiment. FIG. 34 is a schematic sectional view illustrating a configuration of a portion of the semiconductor memory device, and illustrates an XY cross section of the structure illustrated in FIG. 33 cut along a line E-E′ and viewed in a direction of an arrow. FIG. 34 illustrates an XY cross section at a height position corresponding to a conductive layer 110 (SGD). FIG. 35 is a schematic sectional view illustrating a configuration of a portion of the semiconductor memory device, and illustrates the cross section of the structure illustrated in FIG. 33 cut along a line F-F′ and viewed in a direction of an arrow. FIG. 35 illustrates an XY cross section at a height position corresponding to an insulating layer 101.

The semiconductor memory device according to the second embodiment is basically configured in the same manner as the semiconductor memory device according to the first embodiment. However, the semiconductor memory device according to the second embodiment is provided with an inter-string unit insulating member SHE2 instead of the inter-string unit insulating member SHE.

The inter-string unit insulating member SHE2 is basically configured in the same manner as the inter-string unit insulating member SHE. Here, the inter-string unit insulating member SHE2 includes a region R3 instead of the region R1.

The region R3 is basically configured the same as the region R1. Here, the width Y_{R1} (FIG. 34) of the region R3 in the Y direction at the height position corresponding to the plurality of conductive layers 110 (SGDT) and 110 (SGD), and a portion of the conductive layer 110 (DWD) is larger than a width Y_{R3} (FIG. 35) in the Y direction at the height position corresponding to the insulating layers 101 provided on the upper and lower surfaces of these conductive layers 110. In the process illustrated with reference to FIGS. 21 and 22, the width of the groove SHEC in the Y direction is smaller than the width of the groove SHEA in the Y direction by the protective film SHEB provided on the inner wall surface of the groove SHEA in the Y direction. Therefore, the width Y_{R3} is smaller than the width Y_{R2}.

In addition, the region R3 does not include the void V as illustrated with reference to FIG. 4 and the like. However, the inter-string unit insulating member SHE2 may include a void V inside the region R3.

In addition, in the region R3, as illustrated in FIGS. 34 and 35, of two semiconductor pillar arrays SC adjacent in the Y direction via the inter-string unit insulating member SHE2, the distance in the Y direction from the end of the plurality of semiconductor pillar 120 included in one row on the inter-string unit insulating member SHE2 side to the end of the plurality of semiconductor pillar 120 included in the other row on the inter-string unit insulating member SHE2 side is approximately equal to the width Y_{R1} and is larger than widths Y_{R2} and Y_{R3}.

Similarly, of two semiconductor pillar arrays SC adjacent in the Y direction with the inter-string unit insulating member SHE2 interposed therebetween, the distance in the Y direction from the end of the plurality of charge storage films 132 corresponding to the plurality of semiconductor pillars 120 included in one row on the inter-string unit insulating member SHE2 side to the end of the plurality of charge storage films 132 corresponding to the plurality of semiconductor pillars 120 included in the other row on the inter-string unit insulating member SHE2 side is approximately equal to the width Y_{R1} and is larger than the widths Y_{R2} and Y_{R3}.

In addition, in the height position corresponding to the plurality of conductive layers 110 (SGDT) and 110 (SGD), and a portion of the conductive layer 110 (DWD) of the region R3, of two semiconductor pillar arrays SC adjacent in the Y direction with the inter-string unit insulating member SHE2 interposed therebetween, the distance in the Y direction from the end of the high dielectric constant insulating films 103 corresponding to the plurality of semiconductor pillars 120 included in one row on the inter-string unit insulating member SHE2 side to the end of the high dielectric constant insulating films 103 corresponding to the plurality of semiconductor pillars 120 included in the other row on the inter-string unit insulating member SHE2 side is approximately equal to the width Y_{R1} and is larger than the widths Y_{R2} and Y_{R3}.

According to the second embodiment, as in the first embodiment, it is possible to provide a semiconductor memory device that operates favorably without causing a decrease in yield. In addition, in the process illustrated with reference to FIG. 24 and the process illustrated with reference to FIG. 27, by removing a portion of the semiconductor pillar 120, a portion of the charge storage film 132, and a portion of the high dielectric constant insulating film 103 via the groove SHEC, it is possible to provide a semiconductor memory device that operates more favorably.

Moreover, according to the second embodiment, it is possible to reduce the number of manufacturing processes compared to the first embodiment.

### Third Embodiment

As described above, in the first embodiment, at least one of the processes of removing a portion of the high dielectric constant insulating film 103 via the groove SHEC (FIG. 24), removing a portion of the semiconductor pillar 120 via the groove SHEC (FIG. 27), and removing a portion of the charge storage film 132 via the groove SHEC (FIG. 27) may be omitted. This also applies to the second embodiment. Hereinafter, a configuration manufactured by omitting all of these processes in the manufacturing method according to the second embodiment will be exemplified as a semiconductor memory device according to the third embodiment.

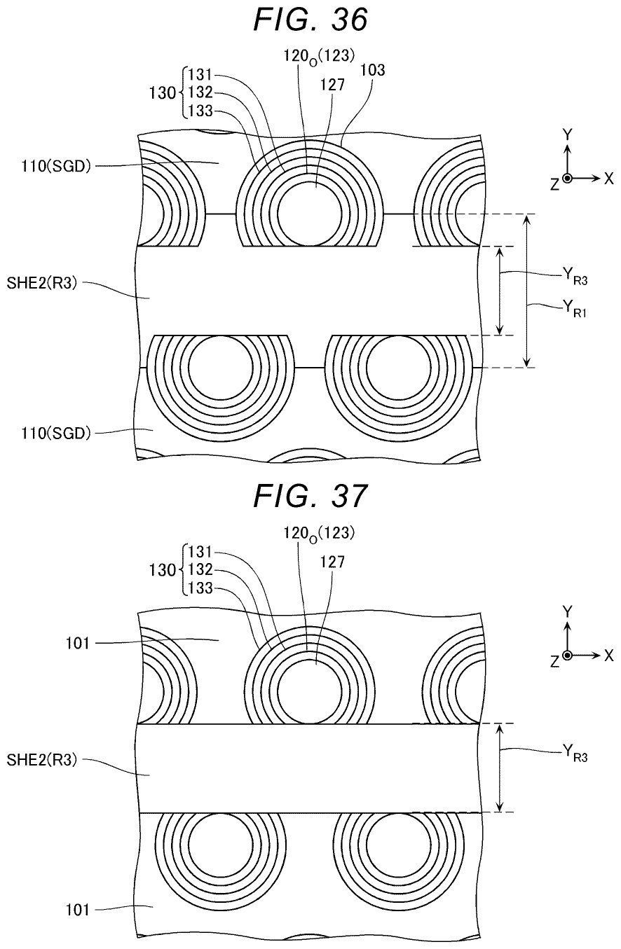

FIGS. 36 and 37 are schematic sectional views illustrating a configuration of a portion of a semiconductor memory device according to the third embodiment. FIG. 36 illustrates a cross section at a position corresponding to FIG. 34. FIG. 37 illustrates a cross section at a position corresponding to FIG. 35.

The semiconductor memory device according to the third embodiment is basically configured in the same manner as the semiconductor memory device according to the second embodiment.

Here, as illustrated in FIGS. 36 and 37, of two semiconductor pillar arrays SC adjacent in the Y direction with the inter-string unit insulating member SHE2 interposed therebetween, the distance in the Y direction from the end of the plurality of semiconductor pillars 120 included in one row on the inter-string unit insulating member SHE2 side to the end of the plurality of semiconductor pillars 120 included in the other row on the inter-string unit insulating member SHE2 side is approximately equal to the width Y_{R3} and is smaller than width Y_{R1} and Y_{R2}.

Similarly, of two semiconductor pillar arrays SC adjacent in the Y direction with the inter-string unit insulating member SHE2 interposed therebetween, the distance in the Y direction from the end of the plurality of gate insulating films 130 corresponding to the plurality of semiconductor pillars 120 included in one row on the inter-string unit insulating member SHE2 side to the end of the plurality of gate insulating films 130 corresponding to the plurality of semiconductor pillars 120 included in the other row on the inter-string unit insulating member SHE2 side is approximately equal to the width Y_{R3} and is smaller than the width Y_{R1} and Y_{R2}.

For example, of two semiconductor pillar arrays SC adjacent in the Y direction with the inter-string unit insulating member SHE2 interposed therebetween, the distance in the Y direction from the end of the plurality of charge storage films 132 corresponding to the plurality of semiconductor pillars 120 included in one row on the inter-string unit insulating member SHE2 side to the end of the plurality of charge storage films 132 corresponding to the plurality of semiconductor pillars 120 included in the other row on the inter-string unit insulating member SHE2 side is approximately equal to the width Y_{R3} and is smaller than the width Y_{R1} and Y_{R2}.

In addition, of two semiconductor pillar arrays SC adjacent in the Y direction with the inter-string unit insulating member SHE2 interposed therebetween, the distance in the Y direction from the end of the high dielectric constant insulating films 103 corresponding to the plurality of semiconductor pillars 120 included in one row on the inter-string unit insulating member SHE2 side to the end of the high dielectric constant insulating films 103 corresponding to the plurality of semiconductor pillars 120 included in the other row on the inter-string unit insulating member SHE2 side is approximately equal to the width Y_{R3} and is smaller than the width Y_{R1} and Y_{R2}.

Also in the semiconductor memory device according to the third embodiment, as in the first embodiment, it is possible to provide a semiconductor memory device that operates favorably without causing a decrease in yield.

Moreover, according to the third embodiment, it is possible to further reduce the number of manufacturing processes compared to the second embodiment.

### Fourth Embodiment

### Configuration

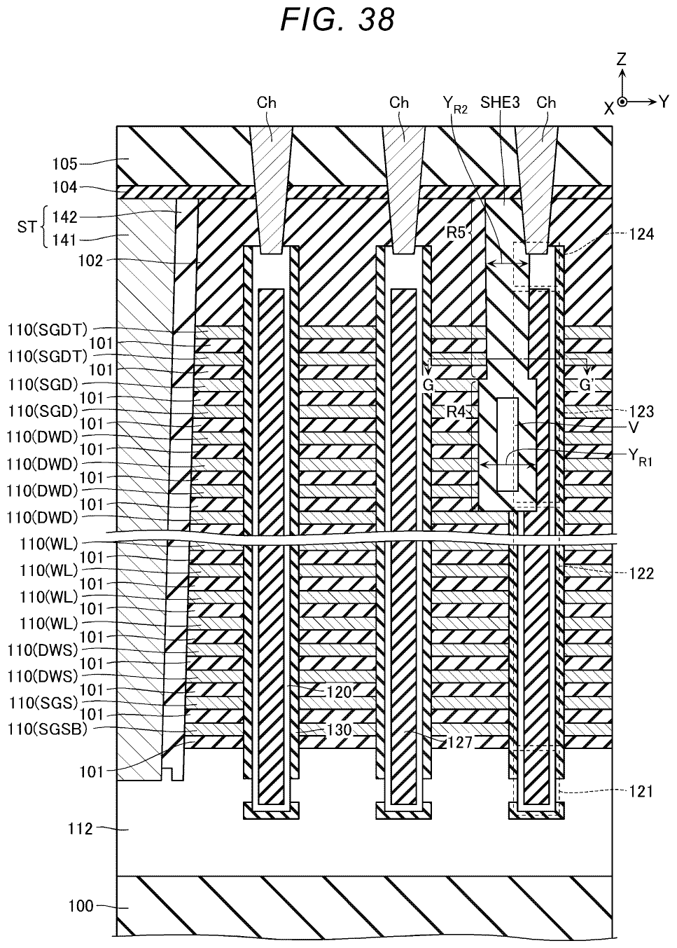

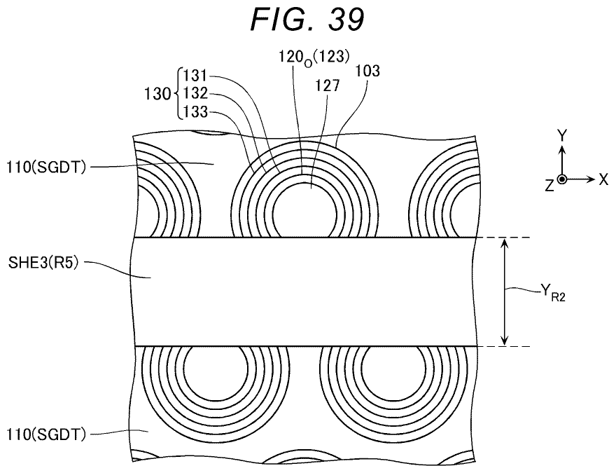

FIG. 38 is a schematic sectional view illustrating a configuration of a portion of the semiconductor memory device according to the fourth embodiment. FIG. 39 is a schematic sectional view illustrating a configuration of a portion of the semiconductor memory device, and illustrates the cross section of the structure illustrated in FIG. 38 cut along a line G-G′ and viewed in a direction of an arrow. FIG. 39 illustrates an XY cross section at a height position corresponding to the conductive layer 110 (SGDT).

The semiconductor memory device according to the fourth embodiment is basically configured in the same manner as the semiconductor memory device according to the first embodiment. Here, the semiconductor memory device according to the fourth embodiment includes an inter-string unit insulating member SHE3 instead of the inter-string unit insulating member SHE.

The inter-string unit insulating member SHE3 is basically configured in the same manner as the inter-string unit insulating member SHE. Here, inter-string unit insulating member SHE3 includes the regions R4 and R5 instead of the regions R1 and R2.

The region R4 is basically configured in the same manner as the region R1. Here, unlike the region R1, the region R4 is not provided at a height position corresponding to one or more conductive layers 110 (SGDT). That is, the region R4 extends in the Z direction in a height range corresponding to the plurality of conductive layers 110 (SGD) and a portion of the conductive layer 110 (DWD), as well as the insulating layers 101 provided on the upper and lower surfaces of these conductive layers 110, and divides these configurations in the Y direction. In addition, the inside of region R4 may or may not include a void V as illustrated with reference to FIG. 4 and the like.

The region R5 is basically configured in the same manner as the region R2. Here, unlike the region R2, the region R5 is also provided at a height position corresponding to one or more conductive layers 110 (SGDT). That is, the region R5 extends in the Z direction in a height range corresponding to the insulating layer 102 and the plurality of conductive layers 110 (SGDT), as well as the insulating layers 101 provided on the upper and lower surfaces of these conductive layers 110, and divides these configurations in the Y direction.

In addition, in the height range corresponding to the region R5, as illustrated in FIG. 39, of two semiconductor pillar arrays SC adjacent in the Y direction with the inter-string unit insulating member SHE3 interposed therebetween, the distance in the Y direction from the end of the plurality of semiconductor pillars 120 included in one row on the inter-string unit insulating member SHE3 side to the end of the plurality of semiconductor pillars 120 included in the other row on the inter-string unit insulating member SHE3 side is approximately equal to the width Y_{R2} and is smaller than the width Y_{R1}.

Similarly, of two semiconductor pillar arrays SC adjacent in the Y direction with the inter-string unit insulating member SHE3 interposed therebetween, the distance in the Y direction from the end of the plurality of gate insulating films 130 corresponding to the plurality of semiconductor pillars 120 included in one row on the inter-string unit insulating member SHE3 side to the end of the plurality of gate insulating films 130 corresponding to the plurality of semiconductor pillars 120 included in the other row on the inter-string unit insulating member SHE3 side is approximately equal to the width Y_{R2} and is smaller than the width Y_{R1}.

For example, of two semiconductor pillar arrays SC adjacent in the Y direction with the inter-string unit insulating member SHE3 interposed therebetween, the distance in the Y direction from the end of the plurality of charge storage films 132 corresponding to the plurality of semiconductor pillars 120 included in one row on the inter-string unit insulating member SHE3 side to the end of the plurality of charge storage films 132 corresponding to the plurality of semiconductor pillars 120 included in the other row on the inter-string unit insulating member SHE3 side is approximately equal to the width Y_{R2} and is smaller than the width Y_{R1}.

In addition, of two semiconductor pillar arrays SC adjacent in the Y direction with the inter-string unit insulating member SHE3 interposed therebetween, the distance in the Y direction from the end of the plurality of high dielectric constant insulating films 103 corresponding to the plurality of semiconductor pillars 120 included in one row on the inter-string unit insulating member SHE3 side to the end of the plurality of high dielectric constant insulating films 103 corresponding to the plurality of semiconductor pillars 120 included in the other row on the inter-string unit insulating member SHE3 side is approximately equal to the width Y_{R2} and is smaller than the width Y_{R1}.

### Manufacturing Method

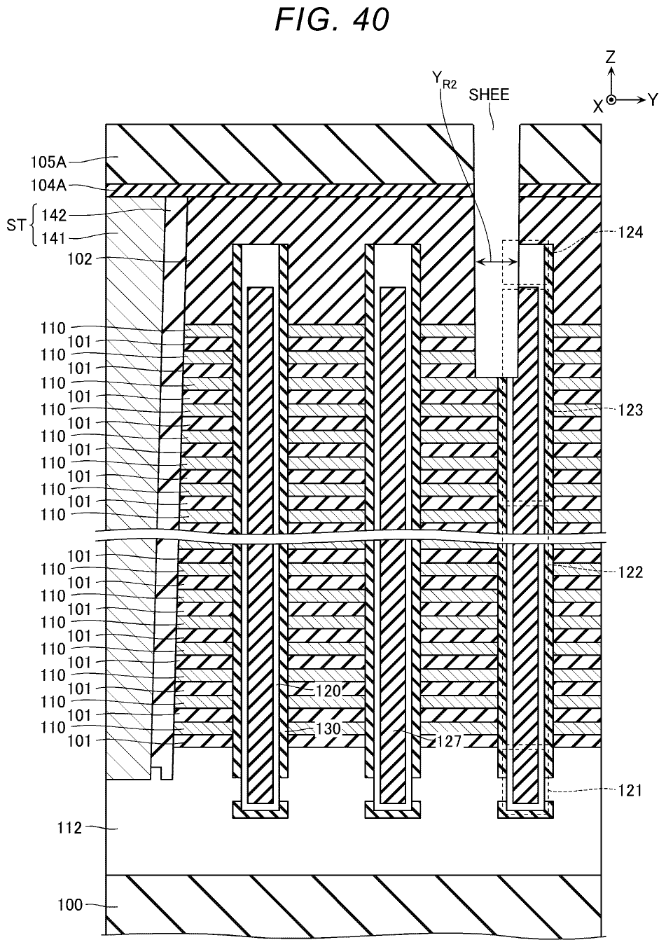

Next, a method for manufacturing a semiconductor memory device according to the fourth embodiment will be illustrated with reference to FIGS. 40 to 42. FIGS. 40 to 42 are schematic sectional views illustrating the same manufacturing method, and illustrate cross sections corresponding to FIG. 38.

The semiconductor memory device according to the fourth embodiment can be basically manufactured in the same manner as the semiconductor memory device according to the first embodiment.

Here, in the manufacturing of the semiconductor memory device according to the fourth embodiment, a groove SHEE is formed instead of the groove SHEA as illustrated in FIG. 40 in the process illustrated with reference to FIGS. 17 and 18. The groove SHEE extends in the Z direction and the X direction, divides the insulating layer 102, the plurality of conductive layers 110 (SGDT), and the insulating layer 101 provided on the upper and lower surfaces thereof in the Y direction, and exposes the upper surface of the uppermost conductive layer 110 (SGD), as well as a portion of the semiconductor pillar 120, the gate insulating film 130, and the insulating pillar 127.

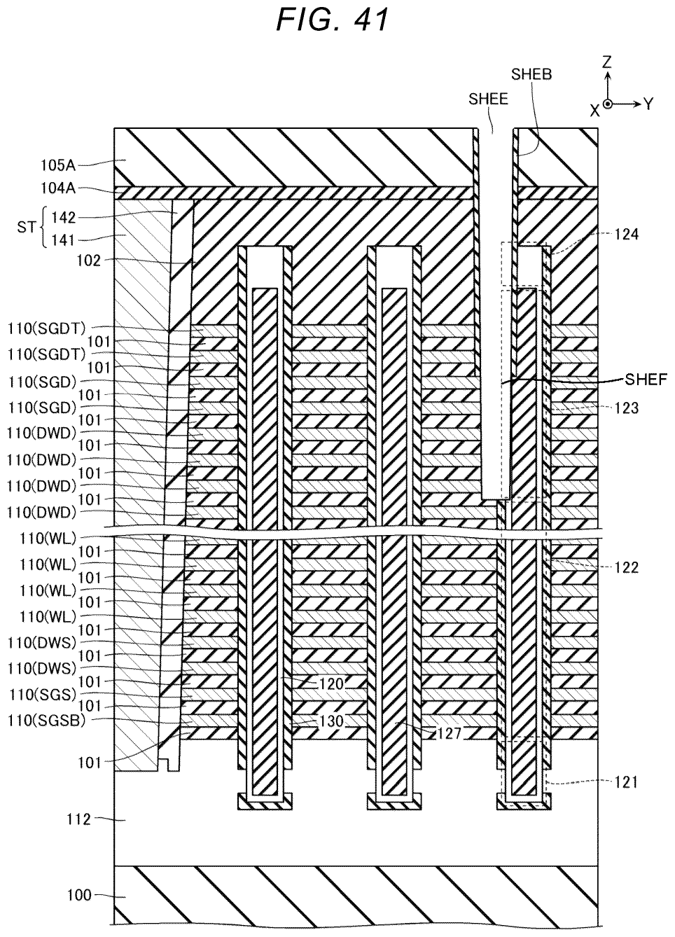

In the process illustrated with reference to FIGS. 21 and 22, a groove SHEF is formed instead of the groove SHEC as illustrated in FIG. 41. The groove SHEF extends in the Z direction and the X direction, divides the plurality of conductive layers 110 (SGD), a portion of the conductive layer 110 (DWD), and the insulating layer 101 provided therebetween in the Y direction.

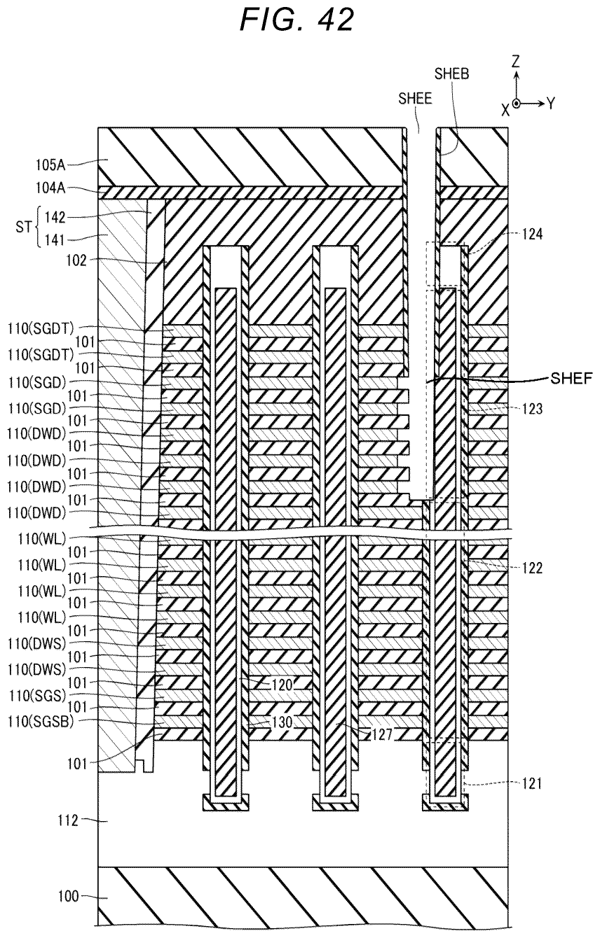

In addition, in the process illustrated in FIGS. 23 and 24, as illustrated in FIG. 42, in a state where the plurality of conductive layers 110 (SGDT) are protected by the protective film SHEB, the width of the groove SHEF in the Y direction is increased at a height position corresponding to a portion of the plurality of conductive layers 110 (SGD) and the conductive layer 110 (DWD). Next, similarly to the first embodiment, in the process illustrated with reference to FIGS. 25 and 26, the width of the groove SHEF in the Y direction is increased at a height position corresponding to the insulating layer 101.

### Effects

As illustrated with reference to FIG. 1, the drain-side selection gate line SGD is electrically independent for each string unit SU. This is because, as described above, the drain-side selection gate line SGD is used to select the string unit SU. On the other hand, the drain-side selection gate line SGDT is electrically common to all the string units SU in the memory block BLK. This is because the drain-side selection gate line SGDT is used not to select the string unit SU but to generate gate induced drain leakage (GIDL) during an erase operation.

That is, in the erase operation, a positive erase voltage is supplied to the semiconductor pillar 120, and the voltage of the conductive layer 110 (WL) is set to a magnitude approximately equal to a ground voltage, so that electrons stored in the charge storage film 132 are drawn to the conductive layer 110 (WL) side. Here, when the voltage of the semiconductor pillar 120 is larger than the voltage of the conductive layer 110 (WL) and the voltage difference therebetween is equal to or larger than a predetermined value, a hole channel (inversion layer) is formed on the outer peripheral surface of the semiconductor pillar 120. On the other hand, since the semiconductor pillar 120 is connected to the source line SL via the region 121 containing N-type impurities, holes cannot be directly supplied from the source line SL to the semiconductor pillar 120. In addition, since the semiconductor pillar 120 is connected to the bit line BL via the end region 124 containing N-type impurities, holes cannot be directly supplied from the bit line BL to the semiconductor pillar 120.

Therefore, in the erase operation, in order to supply the erase voltage to the semiconductor pillar 120 with the voltage of the conductive layer 110 (WL) set to a magnitude approximately equal to the ground voltage, a reverse bias voltage is supplied between the source line SL and the conductive layer 110 (SGSB) and between the bit line BL and the conductive layer 110 (SGDT), for example. As a result, band-to-band tunneling (GIDL) is generated in the region 121 and the end region 124, thereby supplying holes to the outer peripheral surface of the semiconductor pillar 120.

Here, the erase operation is basically performed in units of memory blocks (BLK). Therefore, for example, during the erase operation, even if the semiconductor pillar 120_{O} provided on one side in the Y direction with respect to the inter-string unit insulating member SHE is affected by an electric field from the conductive layer 110 (SGDT) provided on the other side in the Y direction with respect to the inter-string unit insulating member SHE, no hindrance to the operation occurs. That is, at the height position corresponding to the conductive layer 110 (SGDT), it is not necessary to increase the width of the inter-string unit insulating member SHE in the Y direction.

In addition, from the viewpoint of generating holes by GIDL, it is desirable that the area of the opposing surface between the semiconductor pillar 120 and the conductive layer 110 (SGDT) is large. This is because the amount of holes generated by the GIDL per unit time is proportional to the area of the opposing surfaces. Therefore, at the height position corresponding to the conductive layer 110 (SGDT), it is better to not increase the width of the inter-string unit insulating member SHE in the Y direction in order to perform the erase operation favorably.

Therefore, in the present embodiment, as illustrated with reference to FIG. 42, with the plurality of conductive layers 110 (SGDT) protected by the protective film SHEB, the width of the groove SHEF in the Y direction is increased at a height position corresponding to a portion of the plurality of conductive layers 110 (SGD) and the conductive layer 110 (DWD). According to this method, it is possible to provide the semiconductor memory device that can select the string unit SU in the memory block BLK and perform the erase operation in the units of memory block BLK in a favorable manner without causing a decrease in yield.

Also in the fourth embodiment, similarly to the first embodiment, by performing the processes of removing a portion of the high dielectric constant insulating film 103 via the groove SHEF (FIG. 24), removing a portion of the semiconductor pillar 120 via the groove SHEF (FIG. 27), and removing a portion of the charge storage film 132 via the groove SHEF (FIG. 27), it is possible to provide a semiconductor memory device that operates more favorably. In addition, the inner wall surface of the groove SHEF is made relatively flat, and the insulating member SHED can be favorably formed.

Also in the fourth embodiment, similarly to the first embodiment, at least one of the processes of removing a portion of the high dielectric constant insulating film 103 via the groove SHEF (FIG. 24), removing a portion of the semiconductor pillar 120 via the groove SHEF (FIG. 27), and removing a portion of the charge storage film 132 via the groove SHEF (FIG. 27) may be omitted. This makes it possible to reduce the number of manufacturing processes.

### Fifth Embodiment

Also in the fourth embodiment, similarly to the second embodiment, the processes illustrated with reference to FIGS. 25 and 26 may be omitted. Hereinafter, a configuration manufactured by omitting this process will be exemplified as a semiconductor memory device according to the fifth embodiment.

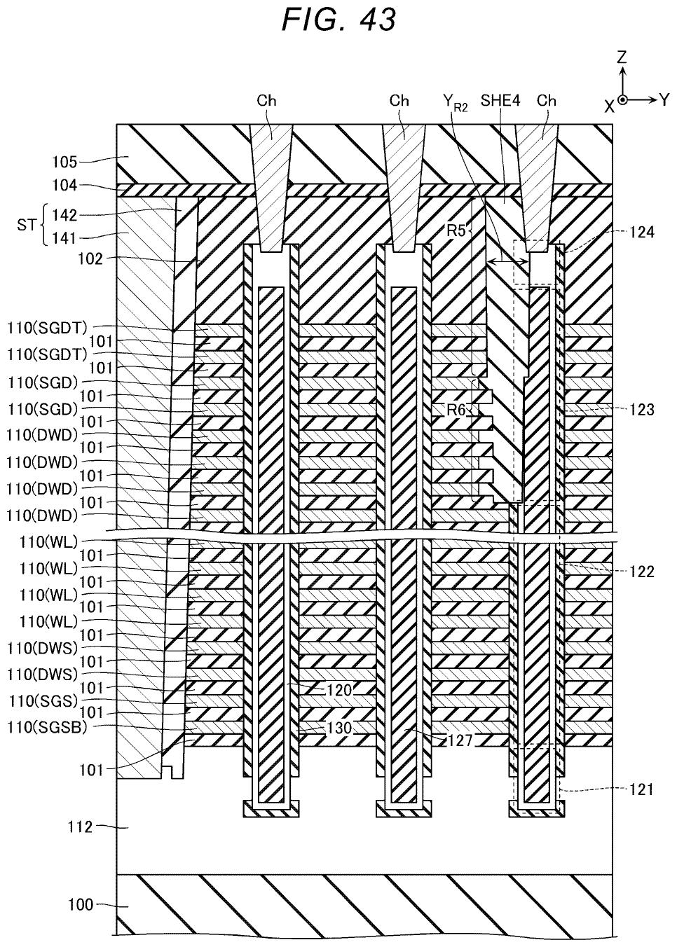

FIG. 43 is a schematic sectional view illustrating a configuration of a portion of a semiconductor memory device according to a fifth embodiment.

The semiconductor memory device according to the fifth embodiment is basically configured in the same manner as the semiconductor memory device according to the fourth embodiment. However, the semiconductor memory device according to the fifth embodiment is provided with an inter-string unit insulating member SHE4 instead of the inter-string unit insulating member SHE3.

The inter-string unit insulating member SHE4 is basically configured in the same manner as the inter-string unit insulating member SHE3. Here, the inter-string unit insulating member SHE4 includes a region R6 instead of the region R4.

The region R6 is basically configured the same as the region R4. Here, a width of the region R6 in the Y direction at the height position corresponding to the plurality of conductive layers 110 (SGD) and a portion of the conductive layer 110 (DWD) is larger than a width in the Y direction at the height position corresponding to the insulating layers 101 provided on the upper and lower surfaces of these conductive layers 110. The width of the region R6 in the Y direction at the height position corresponding to the insulating layer 101 is smaller than the width Y_{R2}.

Moreover, the region R6 does not include the void V as illustrated in FIG. 38. However, the inter-string unit insulating member SHE4 may include the void V inside the region R6.

In addition, in the region R6, as illustrated in FIGS. 34 and 35, of two semiconductor pillar arrays SC adjacent in the Y direction with the inter-string unit insulating member SHE4 interposed therebetween, the distance in the Y direction from the end of the plurality of semiconductor pillars 120 included in one row on the inter-string unit insulating member SHE4 side to the end of the plurality of semiconductor pillars 120 included in the other row on the inter-string unit insulating member SHE4 side is approximately equal to the width Y_{R1} and is larger than widths Y_{R2} and Y_{R3}.

Similarly, of two semiconductor pillar arrays SC adjacent in the Y direction with the inter-string unit insulating member SHE4 interposed therebetween, the distance in the Y direction from the end of the plurality of charge storage films 132 corresponding to the plurality of semiconductor pillars 120 included in one row on the inter-string unit insulating member SHE4 side to the end of the plurality of charge storage films 132 corresponding to the plurality of semiconductor pillars 120 included in the other row on the inter-string unit insulating member SHE4 side is approximately equal to the width Y_{R1} and is larger than the widths Y_{R2} and Y_{R3}.

In addition, in the height position corresponding to the plurality of conductive layers 110 (SGD) and a portion of the conductive layer 110 (DWD) of the region R6, of two semiconductor pillar arrays SC adjacent in the Y direction with the inter-string unit insulating member SHE4 interposed therebetween, the distance in the Y direction from the end of the high dielectric constant insulating films 103 corresponding to the plurality of semiconductor pillars 120 included in one row on the inter-string unit insulating member SHE4 side to the end of the high dielectric constant insulating films 103 corresponding to the plurality of semiconductor pillars 120 included in the other row on the inter-string unit insulating member SHE4 side is approximately equal to the width Y_{R1} and is larger than the widths Y_{R2} and Y_{R3}.

According to the fifth embodiment, as in the fourth embodiment, it is possible to provide the semiconductor memory device that can select the string unit SU in the memory block BLK and perform the erase operation in the units of memory block BLK in a favorable manner without causing a decrease in yield. Also, by performing the processes of removing a portion of the high dielectric constant insulating film 103 via the groove SHEF (FIG. 24), removing a portion of the semiconductor pillar 120 via the groove SHEF (FIG. 27), and removing a portion of the charge storage film 132 via the groove SHEF (FIG. 27), it is possible to provide a semiconductor memory device that operates more favorably.

Moreover, according to the fifth embodiment, it is possible to reduce the number of manufacturing processes compared to the fourth embodiment.

Also in the fifth embodiment, similarly to the fourth embodiment, at least one of the processes of removing a portion of the high dielectric constant insulating film 103 via the groove SHEF (FIG. 24), removing a portion of the semiconductor pillar 120 via the groove SHEF (FIG. 27), and removing a portion of the charge storage film 132 via the groove SHEF (FIG. 27) may be omitted. This makes it possible to reduce the number of manufacturing processes.

### Other Embodiments

In the first and fourth embodiments, the process of removing a portion of the conductive layer 110 (FIGS. 23 and 24) and the process of removing a portion of the insulating layer 101 (FIGS. 25 and 26) may be performed in the reverse order. In such a case, the lower ends of the regions R1 and R4 are provided along the upper surface of any of the insulating layers 101 provided between the lowermost conductive layer 110 (SGD) and the uppermost conductive layer (WL).

In the first and fourth embodiments, the process of removing a portion of the conductive layer 110 and the process of removing a portion of the insulating layer 101 can be performed simultaneously. For example, it is possible to use chemicals, gases, and the like that can remove both the conductive layer 110 and the insulating layer 101.

### Others

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device, comprising:
a plurality of conductive layers stacked in a stacking direction and extending in a first direction intersecting with the stacking direction;
a first semiconductor pillar extending in the stacking direction, facing the plurality of conductive layers, and including impurities in a first end region along the stacking direction;
a first gate insulating film provided between the plurality of conductive layers and the first semiconductor pillar;
a first contact electrode connected to the first end region;
a second semiconductor pillar spaced from the first semiconductor pillar in a second direction intersecting with the stacking direction and the first direction, extending in the stacking direction, facing the plurality of conductive layers, and including impurities in a second end region along the stacking direction;
a second gate insulating film provided between the plurality of conductive layers and the second semiconductor pillar;
a second contact electrode connected to the second end region; and
an insulating member provided between the first semiconductor pillar and the second semiconductor pillar, the insulating member overlapping a portion of the first semiconductor pillar and a portion of the second semiconductor pillar when viewed in the stacking direction, extending in the first direction, and dividing a portion of the conductive layers arranged on a side of the first contact electrode and the second contact electrode in the stacking direction among the plurality of conductive layers in the second direction,
wherein a first width of the insulating member in the second direction at a position in the stacking direction corresponding to a first conductive layer of the conductive layers divided in the second direction by the insulating member is larger than a second width of the insulating member in the second direction at a position in the stacking direction corresponding to the first end region and the second end region and on a side of the plurality of conductive layers with respect to the first contact electrode and the second contact electrode.

2. The semiconductor memory device according to claim 1,
wherein the first width is a distance in the second direction between two parts of the first conductive layer divided in the second direction by the insulating member, and
the second width is a distance in the second direction from a surface of the first end region on the insulating member side to a surface of the second end region on the insulating member side.

3. The semiconductor memory device according to claim 1, further comprising:
a first insulating layer provided between the first conductive layer and a second conductive layer of the conductive layers and divided in the second direction by the insulating member, the second conductive layer being disposed adjacent to the first conductive layer in the stacking direction and divided in the second direction by the insulating member,
wherein a width of the insulating member in the second direction at a position in the stacking direction corresponding to the first insulating layer is larger than the second width.

4. The semiconductor memory device according to claim 3,
wherein the width of the insulating member in the second direction at the position in the stacking direction corresponding to the first insulating layer is a distance in the second direction between two parts of the first insulating layer divided in the second direction by the insulating member.

5. The semiconductor memory device according to claim 3, further comprising:
a second insulating layer provided on a side of the first contact electrode and the second contact electrode in the stacking direction with respect to the plurality of conductive layers,
wherein the insulating member includes:
a first region extending in the stacking direction within a range of the stacking direction corresponding to the first conductive layer, the second conductive layer, and the first insulating layer, and dividing the first conductive layer, the second conductive layer, and the first insulating layer in the second direction; and
a second region extending in the stacking direction within a range of the stacking direction corresponding to the second insulating layer and dividing the second insulating layer in the second direction, and
wherein a width of the first region in the second direction is larger than a width of the second region in the second direction.

6. The semiconductor memory device according to claim 1, further comprising:
a first insulating layer provided between the first conductive layer and a second conductive layer of the conductive layers and divided in the second direction by the insulating member, the second conductive layer being disposed adjacent to the first conductive layer in the stacking direction and divided in the second direction by the insulating member,
wherein a width of the insulating member in the second direction at a position in the stacking direction corresponding to the first insulating layer is smaller than the first width.

7. The semiconductor memory device according to claim 6,
wherein the width of the insulating member in the second direction at the position in the stacking direction corresponding to the first insulating layer is a distance in the second direction between two parts of the first insulating layer divided in the second direction by the insulating member.

8. The semiconductor memory device according to claim 6, further comprising:
a second insulating layer provided on a side of the first contact electrode and the second contact electrode in the stacking direction with respect to the plurality of conductive layers,
wherein the insulating member includes:
a first region extending in the stacking direction within a range of the stacking direction corresponding to the first conductive layer, the second conductive layer, and the first insulating layer, and dividing the first conductive layer, the second conductive layer, and the first insulating layer in the second direction; and
a second region extending in the stacking direction within a range of the stacking direction corresponding to the second insulating layer and dividing the second insulating layer in the second direction, and
wherein a width in the second direction at positions in the stacking direction corresponding to the first conductive layer and the second conductive layer of the first region is larger than a width in the second direction of the second region, and
a width in the second direction at a position in the stacking direction corresponding to the first insulating layer of the first region is smaller than a width in the second direction of the second region.

9. The semiconductor memory device according to claim 1,
wherein at a position in the stacking direction corresponding to the first conductive layer, a distance in the second direction from an end of the first semiconductor pillar on the insulating member side in the second direction to an end of the second semiconductor pillar on the insulating member side in the second direction is larger than the second width.

10. The semiconductor memory device according to claim 1,
wherein at a position in the stacking direction corresponding to the first conductive layer, a distance in the second direction from an end of the first gate insulating film on the insulating member side in the second direction to an end of the second gate insulating film on the insulating member side in the second direction is larger than the second width.

11. The semiconductor memory device according to claim 1,
wherein a third conductive layer of the conductive layers is provided on a side of the first contact electrode and the second contact electrode with respect to the first conductive layer and divided in the second direction by the insulating member, and
a third width of the insulating member in the second direction at a position in the stacking direction corresponding to the third conductive layer is smaller than the first width.

12. The semiconductor memory device according to claim 11,
wherein the third width is a distance in the second direction between two parts of the third conductive layer divided in the second direction by the insulating member.

13. The semiconductor memory device according to claim 11,
wherein two parts of the first conductive layer divided in the second direction by the insulating member are electrically insulated from each other, and
two parts of the third conductive layer divided in the second direction by the insulating member are electrically connected from each other.

14. The semiconductor memory device according to claim 3,
wherein a third conductive layer of the conductive layers is provided on a side of the first contact electrode and the second contact electrode with respect to the first conductive layer and the second conductive layer and divided in the second direction by the insulating member,
a third width of the insulating member in the second direction at a position in the stacking direction corresponding to the third conductive layer is smaller than the first width, and
the width of the insulating member in the second direction at the position in the stacking direction corresponding to the first insulating layer is larger than the third width.

15. The semiconductor memory device according to claim 3, further comprising:
a second insulating layer provided on a side of the first contact electrode and the second contact electrode in the stacking direction with respect to the plurality of conductive layers,
wherein a third conductive layer of the conductive layers is provided on a side of the first contact electrode and the second contact electrode with respect to the first conductive layer and the second conductive layer and divided in the second direction by the insulating member,
wherein the insulating member includes:
a first region extending in the stacking direction within a range of the stacking direction corresponding to the first conductive layer, the second conductive layer, and the first insulating layer, and dividing the first conductive layer, the second conductive layer, and the first insulating layer in the second direction; and
a second region extending in the stacking direction within a range of the stacking direction corresponding to the third conductive layer and the second insulating layer and dividing the third conductive layer and the second insulating layer in the second direction, and
wherein a width of the first region in the second direction is larger than a width of the second region in the second direction.

16. The semiconductor memory device according to claim 6,
wherein a third conductive layer of the conductive layers is provided on a side of the first contact electrode and the second contact electrode with respect to the first conductive layer and the second conductive layer and divided in the second direction by the insulating member,
a third width of the insulating member in the second direction at a position in the stacking direction corresponding to the third conductive layer is smaller than the first width, and
the width of the insulating member in the second direction at the position in the stacking direction corresponding to the first insulating layer is smaller than the third width.

17. The semiconductor memory device according to claim 6, further comprising:
a second insulating layer provided on a side of the first contact electrode and the second contact electrode in the stacking direction with respect to the plurality of conductive layers,
wherein a third conductive layer of the conductive layers is provided on a side of the first contact electrode and the second contact electrode with respect to the first conductive layer and the second conductive layer and divided in the second direction by the insulating member,
wherein the insulating member includes:
a first region extending in the stacking direction within a range of the stacking direction corresponding to the first conductive layer, the second conductive layer, and the first insulating layer, and dividing the first conductive layer, the second conductive layer, and the first insulating layer in the second direction; and
a second region extending in the stacking direction within a range of the stacking direction corresponding to the third conductive layer and the second insulating layer and dividing the third conductive layer and the second insulating layer in the second direction,
wherein a width of the first region in the second direction at positions in the stacking direction corresponding to the first conductive layer and the second conductive layer is larger than a width of the second region in the second direction, and
wherein a width of the first region in the second direction at a position in the stacking direction corresponding to the first insulating layer is smaller than the width of the second region in the second direction.

18. The semiconductor memory device according to claim 11,
wherein at a position in the stacking direction corresponding to the third conductive layer, a distance in the second direction from an end of the first semiconductor pillar on the insulating member side in the second direction to an end of the second semiconductor pillar on the insulating member side in the second direction is smaller than the first width.

19. The semiconductor memory device according to claim 11,
wherein at a position in the stacking direction corresponding to the third conductive layer, a distance in the second direction from an end of the first gate insulating film on the insulating member side in the second direction to an end of the second gate insulating film on the insulating member side in the second direction is smaller than the first width.

20. The semiconductor memory device according to claim 1,
wherein the insulating member does not divide remaining conductive layers other than the portion of the plurality of conductive layers in the second direction.
